(19) United States
(12) Patent Application Publication
(10) Pub. No.: US 2026/0239686 A1
(43) Pub. Date: Aug. 13, 2026

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Ki Sung LEE, Suwon-si (KR); Suk Hyung Park, Suwon-si (KR)

(73) Assignee: SAMSUNG ELECTRONICS CO., LTD., Suwon-si (KR)

(21) Appl. No.: 19/317,626

(22) Filed: Sep. 3, 2025

(30) Foreign Application Priority Data
Feb. 13, 2025 (KR) 10-2025-0018749

(51) Int. Cl. H10D 62/10; H10D 30/00; H10D 30/01; H10D 64/23; H10D 84/01; H10D 84/83

(52) U.S. Cl. CPC H10D 62/115; H10D 30/0191; H10D 30/502; H10D 84/0151; H10D 84/832; H10D 64/256

(57) ABSTRACT

A semiconductor device may include: a substrate; a channel isolation pattern on the substrate, the channel isolation pattern including a first area and a second area, wherein the second area is in a first direction from the first area; a channel pattern on the channel isolation pattern in a second direction crossing the first direction, the channel pattern overlapping with the first area of the channel isolation pattern in the second direction; a gate electrode on the first area of the channel isolation pattern and the second area of the channel isolation pattern in the second direction, the gate electrode extending in the first direction; and a source/drain pattern on at least one side of the gate electrode and connected to the channel pattern, wherein a thickness of the channel isolation pattern in the first area is different from a thickness of the channel isolation pattern in the second area.

### CROSS-REFERENCE TO RELATED APPLICATION

This application claims priority from Korean Patent Application No. 10-2025-0018749, filed on Feb. 13, 2025, in the Korean Intellectual Property Office, and all the benefits accruing therefrom under 35 U.S.C. 119, the disclosure of which is herein incorporated by reference in its entirety.

### BACKGROUND

### 1. Field

Some embodiments of the present disclosure relate to a semiconductor device and a method for manufacturing the same.

### 2. Description of Background Art

As one of scaling techniques for increasing a density of a semiconductor device, a multi-gate transistor has been proposed in which a fin-shaped silicon body is formed on a substrate and a gate is formed on a surface of the silicon body.

Since such a multi-gate transistor uses a three-dimensional channel, it is easy to scale the multi-gate transistor. In addition, current control capability may be improved without increasing a gate length of the multi-gate transistor. In addition, a short channel effect (SCE) in which an electrical potential of a channel area is affected under a drain voltage may be effectively suppressed.

Recently, a technique of increasing a carrier mobility of the channel area of the semiconductor device by forming a layer including a stress material in the fin-shaped silicon body has also been used.

### SUMMARY

According to some embodiments of the present disclosure, a semiconductor device with improved operating characteristics and reliability may be provided.

According to some embodiments of the present disclosure, a method for manufacturing a semiconductor device with improved operating characteristics and reliability may be provided.

According to some embodiments of the present disclosure, a semiconductor device may include: a substrate; a channel isolation pattern on the substrate, the channel isolation pattern including a first area and a second area, wherein the second area is in a first direction from the first area; a channel pattern on the channel isolation pattern in a second direction crossing the first direction, the channel pattern overlapping with the first area of the channel isolation pattern in the second direction; a gate electrode on the first area of the channel isolation pattern and the second area of the channel isolation pattern in the second direction, the gate electrode extending in the first direction; and a source/drain pattern on at least one side of the gate electrode and connected to the channel pattern, wherein a thickness of the channel isolation pattern in the first area of the channel isolation pattern is different from a thickness of the channel isolation pattern in the second area of the channel isolation pattern.

According to some embodiments of the present disclosure, a semiconductor device may include: a substrate; a channel isolation pattern on the substrate, wherein the channel isolation pattern includes a plate portion, a first protrusion portion, and a second protrusion portion, wherein each of the first protrusion portion and the second protrusion portion protrudes from the plate portion of the channel isolation pattern in a first direction, wherein the first protrusion portion and the second protrusion portion are spaced apart from each other in a second direction crossing the first direction; a first channel pattern on the channel isolation pattern in the first direction, and overlapping with the first protrusion portion in the first direction; a second channel pattern on the channel isolation pattern in the first direction, and overlapping with the second protrusion portion in the first direction; a gate electrode on the channel isolation pattern, the first channel pattern, and the second channel pattern, and the gate electrode extending in the second direction; and a source/drain pattern on at least one side of the gate electrode and connected to the first channel pattern.

According to some embodiments of the present disclosure, a semiconductor device may include: a substrate; a channel isolation pattern on the substrate, the channel isolation pattern including a first area and second area, wherein the second area is in a first direction from the first area; a channel pattern on the channel isolation pattern in a second direction crossing the first direction, the channel pattern overlapping with the first area in the second direction, wherein the channel pattern includes a plurality of sheet patterns that are spaced apart from each other in the second direction; a gate electrode on the first area of the channel isolation pattern and the second area of the channel isolation pattern, the gate electrode extending in the first direction; and a source/drain pattern on at least one side of the gate electrode, and connected to the plurality of sheet patterns, wherein a thickness of the channel isolation pattern in the first area of the channel isolation pattern is greater than a thickness of the channel isolation pattern in the second area of the channel isolation pattern, and wherein the gate electrode at least partially surrounds the plurality of sheet patterns in a cross-sectional view of the semiconductor device.

Technical aspects of embodiments of the present disclosure are not limited to the technical aspects mentioned above, and other technical aspects of embodiments of the present disclosure not mentioned may be clearly understood by those skilled in the art from the following description.

Specific details of other embodiments of the present disclosure are included in the detailed description and drawings.

Effects of embodiments of the present disclosure are not limited to those described above, and other effects of embodiments of the present disclosure will be apparent from the following description.

### BRIEF DESCRIPTION OF DRAWINGS

The above and other aspects and features of the present disclosure will become more apparent by describing in detail embodiments thereof with reference to the attached drawings, in which:

FIG. 1 is an example plan view for illustrating a semiconductor device according to some embodiments.

FIG. 2 is a cross-sectional view taken along a line A-A of FIG. 1.

FIG. 3 is a cross-sectional view taken along a line B-B of FIG. 1.

FIG. 4 is a cross-sectional view taken along a line C-C of FIG. 1.

FIG. 5 is a cross-sectional view taken along a line D-D of FIG. 1.

FIG. 6 is a perspective view for illustrating a shape of an channel isolation pattern of FIGS. 2 to 5.

FIG. 7 is a diagram illustrating a channel isolation pattern of FIG. 3.

FIGS. 8 and 9 are enlarged views of a portion P of FIG. 7, respectively.

FIGS. 10 to 13 are diagrams for illustrating a semiconductor device according to some embodiments.

FIGS. 14 to 16 are diagrams for illustrating a semiconductor device according to some embodiments, respectively.

FIGS. 17 to 19 are diagrams for illustrating semiconductor devices according to some embodiments, respectively.

FIGS. 20 and 21 are diagrams for illustrating a semiconductor device according to some embodiments.

FIGS. 22 and 23 are diagrams for illustrating a semiconductor device according to some embodiments.

FIGS. 24 and 25 are diagrams for illustrating a semiconductor device according to some embodiments.

FIGS. 26 and 27 are diagrams for illustrating a semiconductor device according to some embodiments.

FIG. 28 is a diagram for illustrating a semiconductor device according to some embodiments.

FIGS. 29 to 47 are diagrams illustrating intermediate structures corresponding to intermediate steps of a method for manufacturing a semiconductor device according to some embodiments.

### DETAILED DESCRIPTIONS

It will be understood that, although the terms “first,” “second,” “third,” and so on may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described below could be termed a second element, component, region, layer, or section, without departing from the spirit and scope of the present disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

A semiconductor device according to some embodiments may include a tunneling transistor (e.g., a tunneling field-effect transistor (FET)), a three-dimensional (3D) transistor, or a two-dimensional (2D) material-based FET, and a heterostructure thereof. Further, the semiconductor device according to some embodiments may include a bipolar junction transistor, a lateral double-diffused metal-oxide-semiconductor (LDMOS) transistor, etc.

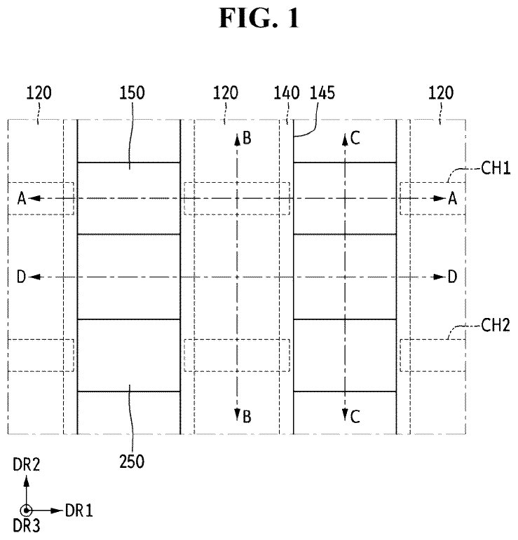

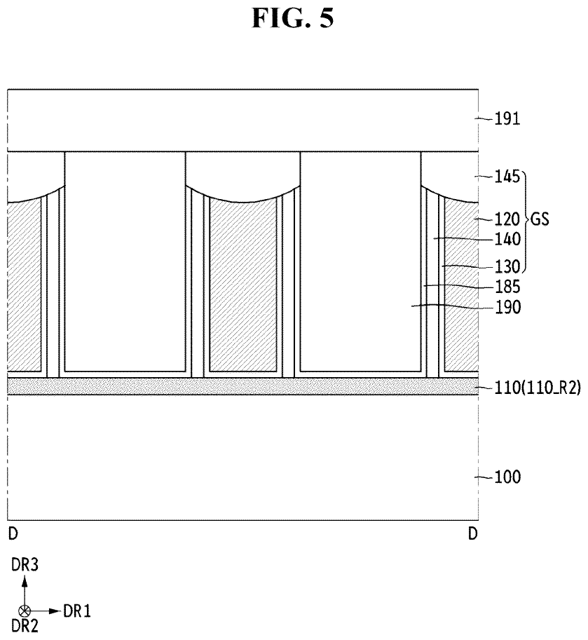

A semiconductor device according to some embodiments will be described with reference to FIGS. 1 to 9.

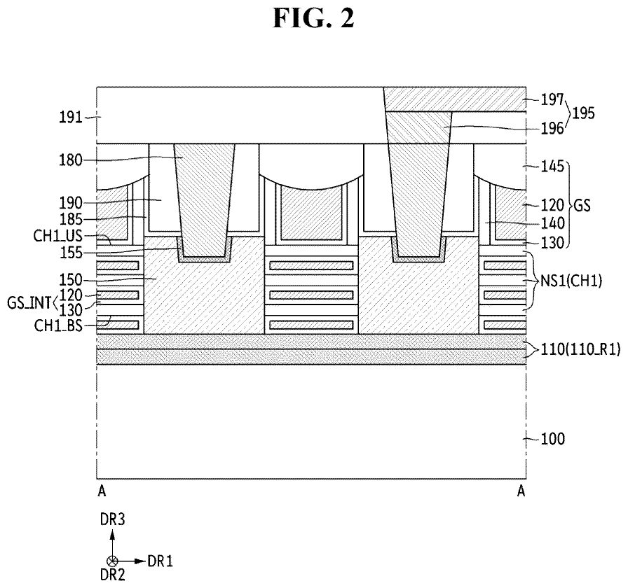

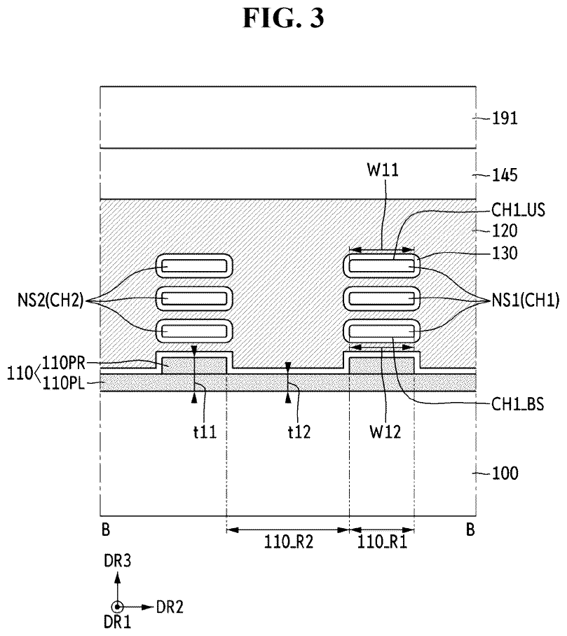

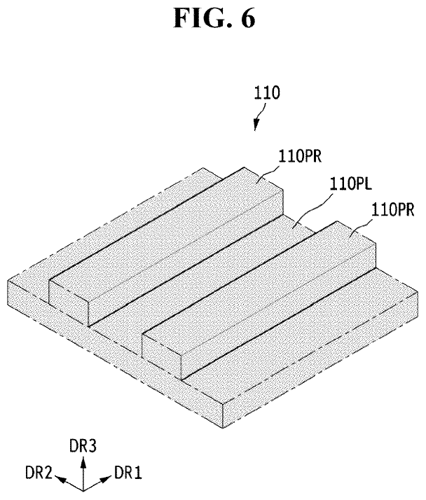

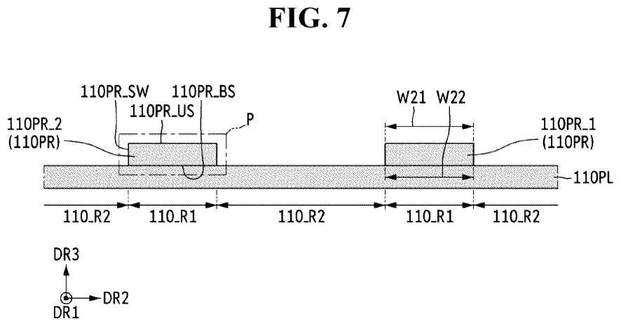

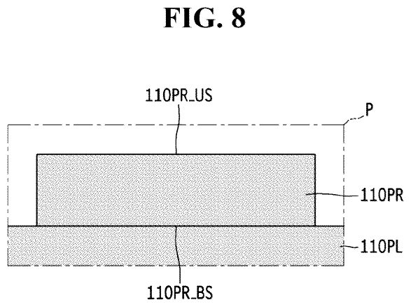

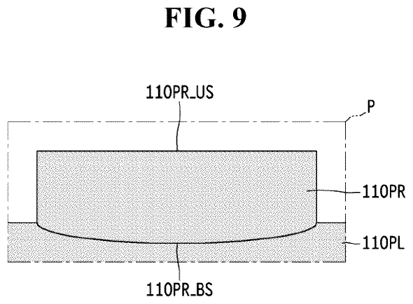

FIG. 1 is an example plan view for illustrating a semiconductor device according to some embodiments. FIGS. 2 to 5 are cross-sectional views taken along lines A-A, B-B, C-C, and D-D of FIG. 1, respectively. FIG. 6 is a perspective view for illustrating a shape of a channel isolation pattern of FIGS. 2 to 5. FIG. 7 is a diagram illustrating a channel isolation pattern of FIG. 3. FIGS. 8 and 9 are enlarged views of a portion P of FIG. 7, respectively.

For reference, FIG. 1 schematically illustrates the semiconductor device except for a gate insulating film 130, a source/drain etch stop film 185, a first interlayer insulating film 190, a second interlayer insulating film 191, a front wiring structure 195, etc.

Referring to FIGS. 1 to 9, the semiconductor device according to some embodiments may include a channel isolation pattern 110, a first channel pattern CH1, a second channel pattern CH2, a gate electrode 120, a first source/drain pattern 150, and a second source/drain pattern 250.

A first substrate 100 may be provided and may be made of bulk silicon or silicon-on-insulator (SOI). Alternatively, the first substrate 100 may be a silicon substrate, or may include a material other than silicon such as, for example, silicon germanium, silicon germanium on insulator (SGOI), indium antimonide, lead telluride compound, indium arsenide, indium phosphide, gallium arsenide, or gallium antimonide. However, embodiments of the present disclosure are not limited thereto.

The channel isolation pattern 110 may be disposed on the first substrate 100. The channel isolation pattern 110 may include a plate portion 110PL and a plurality of protrusion portions 110PR.

Each protrusion portion 110PR of the channel isolation pattern 110 may protrude from the plate portion 110PL of the channel isolation pattern 110 in a third direction DR3. Each protrusion portion 110PR of the channel isolation pattern 110 may protrude in a direction away from the first substrate 100. The plate portion 110PL of the channel isolation pattern 110 may be in contact (e.g., direct contact) with the protrusion portion 110PR of the channel isolation pattern 110.

Each protrusion portion 110PR of the channel isolation pattern 110 may extend in the first direction DR1. The protrusion portions 110PR of the channel isolation pattern 110 may be spaced apart from each other in a second direction DR2. For example, the plurality of protrusion portions 110PR of the channel isolation pattern 110 may include a first protrusion portion 110PR_1 and a second protrusion portion 110PR_2. Each of the first protrusion portion 110PR_1 of the channel isolation pattern 110 and the second protrusion portion 110PR_2 of the channel isolation pattern 110 may extend in the first direction DR1. The first protrusion portion 110PR_1 of the channel isolation pattern 110 may be spaced apart from the second protrusion portion 110PR_2 of the channel isolation pattern 110 in the second direction DR2.

For example, the first direction DR1 and the second direction DR2 may cross (e.g., may be perpendicular to) the third direction DR3. The first direction DR1 may cross (e.g., may be perpendicular to) the second direction DR2.

In FIG. 7, the protrusion portion 110PR of the channel isolation pattern 110 may include an upper surface 110PR_US and a bottom surface 110PR_BS opposite to each other in the third direction DR3. The protrusion portion 110PR of the channel isolation pattern 110 may include sidewalls 110PR_SW opposite to each other in the second direction DR2.

The bottom surface 110PR_BS of the protrusion portion PP of the channel isolation pattern 110 may face towards the first substrate 100. The bottom surface 110PR_BS of the protrusion portion 110SP of the channel isolation pattern 110 may be in contact (e.g., direct contact) with the plate portion 110PL of the channel isolation pattern 110. For example, the bottom surface 110PR_BS of the protrusion portion 110SP of the channel isolation pattern 110 may be a surface of the protrusion portion 110PR of the channel isolation pattern 110 in contact (e.g., direct contact) with the plate portion 110PL of the channel isolation pattern 110. The sidewalls 110PR_SW of the protrusion portion 110SP of the channel isolation pattern 110 connect the upper surface 110PR_US of the protrusion portion 110SP of the channel isolation pattern 110 to the bottom surface 110PR_BS of the protrusion portion 110SP of the channel isolation pattern 110.

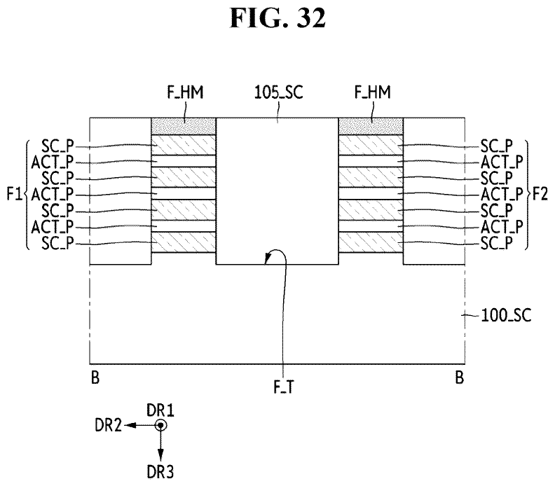

The channel isolation pattern 110 includes an insulating material. The channel isolation pattern 110 may include a material having an etch selectivity with respect to a sacrificial field insulating film 105_SC (see FIG. 32) to be described below. When the sacrificial field insulating film 105_SC includes silicon oxide, the channel isolation pattern 110 may include, for example, silicon nitride, silicon oxynitride, silicon oxycarbonitride, silicon boron nitride, silicon oxyboron nitride, silicon oxycarbide, or a combination thereof. However, embodiments of the present disclosure are not limited thereto. When the material included in the sacrificial field insulating film 105_SC is different from the above-described material, the insulating material that the channel isolation pattern 110 may be changed.

Each of the plate portion 110PL of the channel isolation pattern 110 and the protrusion portion 110PR of the channel isolation pattern 110 may include, but is not limited to, silicon nitride, silicon oxynitride, silicon oxycarbonitride, silicon boron nitride, silicon oxyboron nitride, or silicon oxycarbide.

In one example, the plate portion 110PL of the channel isolation pattern 110 and the protrusion portion 110PR of the channel isolation pattern 110 may include different insulating materials from each other. With reference to FIGS. 8 and 9, a boundary between the plate portion 110PL of the channel isolation pattern 110 and the protrusion portion 110PR of the channel isolation pattern 110 may be the bottom surface 110PR_BS of the protrusion portion PP of the channel isolation pattern 110. In FIG. 8, the boundary between the plate portion 110PL of the channel isolation pattern 110 and the protrusion portion 110PR of the channel isolation pattern 110 may be flat in a cross-sectional view. In FIG. 9, the boundary between the plate portion 110PL of the channel isolation pattern 110 and the protrusion portion 110PR of the channel isolation pattern 110 may include a curved surface in a cross-sectional view.

Unlike the illustrated example, a portion of the protrusion portion 110PR of the channel isolation pattern 110 may protrude into the plate portion 110PL of the channel isolation pattern 110. In this case, the boundary between the plate portion 110PL of the channel isolation pattern and the protrusion portion 110PR of the channel isolation pattern 110 may have a “U” shape or a shape similar to “U” in the cross-sectional view.

In another example, the plate portion 110PL of the channel isolation pattern 110 and the protrusion portion 110PR of the channel isolation pattern 110 may include the same insulating material as each other. In this case, the boundary between the plate portion 110PL of the channel isolation pattern 110 and the protrusion portion 110PR of the channel isolation pattern 110 may not be defined as illustrated in FIGS. 7 to 9. When the boundary between the plate portion 110PL of the channel isolation pattern and the protrusion portion 110PR of the channel isolation pattern is not defined, the bottom surface 110PR_BS of the protrusion portion of the channel isolation pattern may be a portion that starts to protrude in the third direction DR3 from a two-dimensional flat plate.

In the semiconductor device according to some embodiments, a width W21 in the second direction DR2 of the upper surface 110PR_US of the protrusion portion 110SP of the channel isolation pattern may be equal to a width W22 in the second direction DR2 of the bottom surface 110PR_BS of the protrusion portion 110SP of the channel isolation pattern.

The channel isolation pattern 110 may include at least one first area 110_R1 and at least one second area 110_R2. The first areas 110_R1 of the channel isolation pattern and the second areas 110_R2 of the channel isolation pattern 110 may be alternately arranged with each other in the second direction DR2.

A thickness t11 in the third direction DR3 of the channel isolation pattern 110 in the first area 110_R1 of the channel isolation pattern may be different from a thickness t12 in the third direction DR3 of the channel isolation pattern 110 in the second area 110_R2 of the channel isolation pattern. For example, the thickness t11 of the channel isolation pattern 110 in the first area 110_R1 of the channel isolation pattern 110 may be greater than the thickness t12 of the channel isolation pattern 110 in the second area 110_R2 of the channel isolation pattern 110.

The first area 110_R1 of the channel isolation pattern 110 may include a portion of the plate portion 110PL of the channel isolation pattern 110 and the protrusion portion 110PR of the channel isolation pattern 110. The second area 110_R2 of the channel isolation pattern 110 may include a portion of the plate portion 110PL of the channel isolation pattern 110 and may not include the protrusion portion 110PR of the channel isolation pattern 110.

Each of a first channel pattern CH1 and a second channel pattern CH2 may be disposed on the channel isolation pattern 110. The channel isolation pattern 110 may be disposed between the first channel pattern CH1 and the first substrate 100 and between the second channel pattern CH2 and the first substrate 100.

Each of the first channel pattern CH1 and the second channel pattern CH2 may be disposed on the first area 110_R1 of the channel isolation pattern. Each of the first channel pattern CH1 and the second channel pattern CH2 may overlap with the first area 110_R1 of the channel isolation pattern in the third direction DR3.

Each of the first channel pattern CH1 and the second channel pattern CH2 may be disposed on the protrusion portion 110PR of the channel isolation pattern 110. For example, the first channel pattern CH1 may be disposed on the first protrusion portion 110PR_1 of the channel isolation pattern 110. The second channel pattern CH2 may be disposed on the second protrusion portion 110PR_2 of the channel isolation pattern 110.

The first channel pattern CH1 may overlap with the first protrusion portion 110PR_1 of the channel isolation pattern 110 in the third direction DR3. A center line of a width in the second direction DR2 of the first channel pattern CH1 may extend through the first protrusion portion 110PR_1 of the channel isolation pattern. The first channel patterns CH1 may be spaced apart from each other in the first direction DR1 and each of the first channel patterns CH1 may be disposed on the protrusion portion 110PR of the channel isolation pattern 110.

The second channel pattern CH2 may overlap with the second protrusion portion 110PR_2 of the channel isolation pattern 110 in the third direction DR3. A center line of a width in the second direction DR2 of the second channel pattern CH2 may extend through the second protrusion portion 110PR_2 of the channel isolation pattern 110. The second channel patterns CH2 may be spaced apart from each other in the first direction DR1 and each of the second channel patterns CH2 may be disposed on the protrusion portion 110PR of the channel isolation pattern 110. The first channel pattern CH1 and the second channel pattern CH2 may be spaced apart from each other in the second direction DR2.

Each of the first channel pattern CH1 and the second channel pattern CH2 may include a plurality of sheet patterns spaced apart from each other in the third direction DR3. Although each of the first channel pattern CH1 and the second channel pattern CH2 is illustrated as including three sheet patterns, this is intended only for convenience of illustration, and embodiments of the present disclosure are not limited thereto.

The first channel pattern CH1 may include a plurality of first sheet patterns NS1. The plurality of first sheet patterns NS1 may be arranged in the third direction DR3 and may be disposed on the channel isolation pattern 110. The first sheet patterns NS1 may be spaced apart from each other in the third direction DR3.

The second channel pattern CH2 may include a plurality of second sheet patterns NS2. The plurality of first sheet patterns NS2 may be arranged in the third direction DR3 and may be disposed on the channel isolation pattern 110. The second sheet patterns NS2 may be spaced apart from each other in the third direction DR3.

In the semiconductor device according to some embodiments, each of the first channel pattern CH1 and the second channel pattern CH2 may not be in direct contact with the channel isolation pattern 110. For example, each of the first channel pattern CH1 and the second channel pattern CH2 may not be in direct contact with the protrusion portion 110PR of the channel isolation pattern 110. Each of the first sheet patterns NS1 included in the first channel pattern CH1 may be spaced apart from the channel isolation pattern 110 in the third direction DR3. Each of the second sheet patterns NS2 included in the second channel pattern CH2 may be spaced apart from the channel isolation pattern 110 in the third direction DR3.

For example, the first channel pattern CH1 may include an upper surface CH1_US and a bottom surface CH1_BS opposite to each other in the third direction DR3. The bottom surface CH1_BS of the first channel pattern CH1 may not be in direct contact with the first protrusion portion 110PR_1 of the channel isolation pattern 110. The bottom surface CH1_BS of the first channel pattern CH1 may overlap with the first protrusion portion 110PR_1 of the channel isolation pattern 110 in the third direction DR3. Each of the first sheet patterns NS1 may include an upper surface and a bottom surface opposite to each other in the third direction DR3. For example, the bottom surface of each first sheet pattern NS1 may face towards the channel isolation pattern 110. For example, the upper surface of the uppermost first sheet pattern NS1 may be the upper surface CH1_US of the first channel pattern CH1. The bottom surface of the lowermost first sheet pattern NS1 may be the bottom surface CH1_BS of the first channel pattern CH1.

The description of the first channel pattern CH1 may also be applied to the second channel pattern CH2.

In the semiconductor device according to some embodiments, a width W11 in the second direction DR2 of the upper surface CH1_US of the first channel pattern CH1 may be equal to a width W12 in the second direction DR2 of the bottom surface CH1_BS of the first channel pattern CH1.

Each of the first channel pattern CH1 and the second channel pattern CH2 may include silicon or germanium as an elemental semiconductor material. In addition, each of the first channel pattern CH1 and the second channel pattern CH2 may include a compound semiconductor, and may include, for example, a group IV-IV compound semiconductor or a group III-V compound semiconductor.

The group IV-IV compound semiconductor may include, for example, a binary compound including two from among carbon (C), silicon (Si), germanium (Ge), and tin (Sn), a ternary compound including three thereof, or a compound obtained by doping a group IV element thereto.

The group III-V compound semiconductor may include, for example, a binary compound obtained by combining one from among aluminum (Al), gallium (Ga), and indium (In) as a group III element and one from among phosphorus (P), arsenic (As), and antimony (Sb) as a group V element with each other, a ternary compound obtained by combining two from among aluminum (Al), gallium (Ga), and indium (In) as a group III element and one from among phosphorus (P), arsenic (As), and antimony (Sb) as a group V with each other, or a quaternary compound obtained by combining three from among aluminum (Al), gallium (Ga), and indium (In) as a group III element and one from among phosphorus (P), arsenic (As), and antimony (Sb) as a group V with each other.

In an example, the first channel pattern CH1 and the second channel pattern CH2 may be disposed in a p-channel metal-oxide-semiconductor (PMOS) formation area. In another example, the first channel pattern CH1 and the second channel pattern CH2 may be disposed in an n-channel metal-oxide-semiconductor (NMOS) formation area. In another example, one from among the first channel pattern CH1 and the second channel pattern CH2 may be disposed in the PMOS formation area, and the other thereof may be disposed in the NMOS formation area.

A plurality of gate structures GS may be disposed on the first substrate 100. For example, the plurality of gate structures GS may be disposed on the channel isolation pattern 110. The gate structure GS may be disposed on the first channel pattern CH1 and the second channel pattern CH2.

Each gate structure GS may extend in the second direction DR2. The gate structures GS may be spaced apart from each other in the first direction DR1. The gate structures GS may be adjacent to each other in the first direction DR1.

For example, the gate structure GS may be disposed on each of opposing sides in the first direction DR1 of a first source/drain pattern 150. According to some embodiments, the gate structure GS may be disposed on each of opposing sides in the first direction DR1 of a second source/drain pattern 250.

The gate structure GS may include, for example, a gate electrode 120, a gate insulating film 130, a gate spacer 140, and a gate capping pattern 145.

With reference to FIG. 2, the gate structure GS may include an inner gate structure GS_INT disposed between the channel isolation pattern 110 and the lowest first sheet pattern NS1 and between the first sheet patterns NS1 adjacent to each other in the third direction DR3. According to some embodiments, the inner gate structure GS_INT may be disposed between the channel isolation pattern 110 and the lowest second sheet pattern NS2 and between the second sheet patterns NS2 adjacent to each other in the third direction DR3. The inner gate structure GS_INT may include the gate electrode 120 and the gate insulating film 130.

The gate structure GS is illustrated as being disposed over the first channel pattern CH1 and the second channel pattern CH2 adjacent to each other. However, embodiments of the present disclosure are not limited thereto. For example, a portion of the gate structure GS may be divided into two portions which may be disposed on the channel isolation pattern 110. That is, the first gate structure on the first channel pattern CH1 may be isolated from the second gate structure on the second channel pattern CH2 in the second direction DR2. In this case, a first gate electrode and a first gate insulating film included in the first gate structure may be isolated from a second gate electrode and a second gate insulating film included in the second gate structure.

The gate electrode 120 may be disposed on the channel isolation pattern 110. The gate electrode 120 may be disposed on the first area 110_R1 of the channel isolation pattern 110 and the second area 110_R2 of the channel isolation pattern 110. The gate electrode 120 may extend in the second direction DR2. The gate electrode 120 may be disposed on the first channel pattern CH1 and the second channel pattern CH2. For example, the gate electrode 120 may surround each of the first channel pattern CH1 and the second channel pattern CH2. In the semiconductor device according to some embodiments, the gate electrode 120 may surround each of the first sheet patterns NS1 and each of the second sheet patterns NS2.

The gate electrode 120 may include at least one from among a metal, a conductive metal nitride, a metal silicide, a doped semiconductor material, a conductive metal oxide, and a conductive metal oxynitride.

The gate electrode 120 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. However, embodiments of the present disclosure are not limited thereto. The conductive metal oxide and the conductive metal oxynitride may include oxidized products of the above-mentioned materials. However, embodiments of the present disclosure are not limited thereto.

The gate electrode 120 may be disposed on each of opposing sides of the first source/drain pattern 150 to be described later. For example, each of the gate electrodes 120 respectively disposed on opposing sides of the first source/drain pattern 150 may be a normal gate electrode used as a gate of a transistor. In another example, the gate electrode 120 disposed on one side of the first source/drain pattern 150 may be used as a gate of a transistor, while the gate electrode 120 disposed on the other side of the first source/drain pattern 150 may be a dummy gate electrode.

The gate insulating film 130 may be disposed on the channel isolation pattern 110. The gate electrode 120 may be disposed on the gate insulating film 130.

The gate insulating film 130 may be disposed between the gate electrode 120 and the channel isolation pattern 110, between the gate electrode 120 and the first channel pattern CH1, and between the gate electrode 120 and the second channel pattern CH2. The gate insulating film 130 may extend along a profile of each of the plate portion 110PL of the channel isolation pattern 110 and the protrusion portion 110PR of the channel isolation pattern 110.

The gate insulating film 130 may include silicon oxide, silicon-germanium oxide, germanium oxide, silicon oxynitride, silicon nitride, or a high-k material having a higher dielectric constant than a dielectric constant of silicon oxide. The high dielectric constant (high-k) material may include at least one from among, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Although the gate insulating film 130 is illustrated as being embodied as a single film, this is intended only for convenience of illustration, and embodiments of the present disclosure are not limited thereto. The gate insulating film 130 may include a plurality of films. The gate insulating film 130 may include an interfacial film disposed between the gate electrode 120 and the first channel pattern CH1 and between the gate electrode 120 and the second channel pattern CH2, and a high-k insulating film.

The semiconductor device according to some embodiments may include a negative capacitance (NC) FET using a negative capacitor. For example, the gate insulating film 130 may include a ferroelectric material film having ferroelectric properties and a paraelectric material film having paraelectric properties.

The ferroelectric material film may have negative capacitance, and the paraelectric material film may have positive capacitance. For example, when two or more capacitors may be connected in series to each other, and capacitance of each of the capacitors has a positive value, a total capacitance is smaller than capacitance of each individual capacitor. On the contrary, when at least one of capacitances of two or more capacitors connected in series to each other has a negative value, a total capacitance may have a positive value and be greater than an absolute value of each individual capacitance.

When the ferroelectric material film with negative capacitance and the paraelectric material film with positive capacitance are connected in series to each other, a total capacitance value of the ferroelectric material film and the paraelectric material film connected in series to each other may be increased. Using the increase in the total capacitance value, a transistor including the ferroelectric material film may have a subthreshold swing (SS) lower than about 60 mV/decade at room temperature.

The ferroelectric material film may have ferroelectric properties. The ferroelectric material film may include, for example, at least one from among hafnium oxide, hafnium zirconium oxide, barium strontium titanium oxide, barium titanium oxide, and lead zirconium titanium oxide. In this embodiment, in one example, hafnium zirconium oxide may refer to a material obtain by doping hafnium oxide with zirconium (Zr). In another example, hafnium zirconium oxide may refer to a compound of hafnium (Hf), zirconium (Zr), and oxygen (O).

The ferroelectric material film may further contain doped dopants. For example, the dopant may include at least one from among aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of the dopant contained in the ferroelectric material film may vary depending on a type of the ferroelectric material included in the ferroelectric material film.

When the ferroelectric material film includes hafnium oxide, the dopant contained in the ferroelectric material film may include, for example, at least one from among gadolinium (Gd), silicon (Si), zirconium (Zr), aluminum (Al), and yttrium (Y).

When the dopant is aluminum (Al), the ferroelectric material film may contain about 3 to about 8 at % (atomic %) of aluminum. In this embodiment, a content of the dopant may be a content of aluminum based on a sum of hafnium and aluminum.

When the dopant is silicon (Si), the ferroelectric material film may contain about 2 to about 10 at % of silicon. When the dopant is yttrium (Y), the ferroelectric material film may contain about 2 to about 10 at % yttrium. When the dopant is gadolinium (Gd), the ferroelectric material film may contain about 1 to about 7 at % gadolinium. When the dopant is zirconium (Zr), the ferroelectric material film may contain about 50 to about 80 at % zirconium.

The paraelectric material film may have paraelectric properties. The paraelectric material film may include, for example, at least one from among silicon oxide and metal oxide having a high dielectric constant. The metal oxide contained in the paraelectric material film may include, for example, at least one from among hafnium oxide, zirconium oxide, and aluminum oxide. However, embodiments of the present disclosure are not limited thereto.

The ferroelectric material film and the paraelectric material film may include the same material as each other. The ferroelectric material film may have ferroelectric properties, but the paraelectric material film may not have the ferroelectric properties. For example, when each of the ferroelectric material film and the paraelectric material film includes hafnium oxide, a crystal structure of hafnium oxide contained in the ferroelectric material film may be different from a crystal structure of hafnium oxide contained in the paraelectric material film.

The ferroelectric material film may have a thickness sized to exhibit ferroelectric properties. Although the thickness of the ferroelectric material film may be, for example, in a range of about 0.5 nm to about 10 nm, embodiments of the present disclosure are not limited thereto. Because a critical thickness exhibiting the ferroelectric properties may vary based on a type of the ferroelectric material, the thickness of the ferroelectric material film may vary depending on the type of the ferroelectric material.

In one example, the gate insulating film 130 may include one ferroelectric material film. In another example, the gate insulating film 130 may include a plurality of ferroelectric material films spaced apart from each other. The gate insulating film 130 may have a multilayer structure in which a plurality of ferroelectric material films and a plurality of paraelectric material films are alternately stacked on top of each other.

The gate spacer 140 may be disposed on a sidewall of the gate electrode 120. An entirety of the gate spacer 140 may be disposed on the channel isolation pattern 110. The gate spacer 140 may be disposed on the first area 110_R1 of the channel isolation pattern 110 and the second area 110_R2 of the channel isolation pattern 110. The gate spacer 140 may be in contact (e.g., direct contact) with the channel isolation pattern 110.

The gate spacer 140 may include, for example, silicon nitride, silicon oxynitride, silicon oxide, silicon oxycarbonitride, silicon boron nitride, silicon oxyboron nitride, silicon oxycarbide, or a combination thereof. Although the gate spacer 140 is illustrated as being embodied as a single film, this is intended only for convenience of illustration, and embodiments of the present disclosure are not limited thereto.

The gate capping pattern 145 may be disposed on the gate electrode 120 and the gate spacer 140. The gate capping pattern 145 may be disposed on an upper surface of the gate electrode 120. The upper surface of the gate capping pattern 145 may be coplanar with an upper surface of the first interlayer insulating film 190. However, embodiments of the present disclosure are not limited thereto. Unlike the illustrated example, the gate capping pattern 145 may be disposed between the gate spacers 140.

The gate capping pattern 145 may include, for example, silicon nitride, silicon oxynitride, silicon carbonitride, silicon oxycarbonitride, or a combination thereof. The gate capping pattern 145 may include a material having an etch selectivity with respect to the first interlayer insulating film 190.

Unlike the illustrated example, the gate capping pattern 145 may not be disposed on the gate electrode 120. That is, the gate structure GS may not include the gate capping pattern 145.

Each of the first source/drain pattern 150 and the second source/drain pattern 250 may be disposed on the channel isolation pattern 110. Each of the first source/drain pattern 150 and the second source/drain pattern 250 may be disposed on the first area 110_R1 of the channel isolation pattern 110P.

The first source/drain pattern 150 may be disposed on the protrusion portion 110PR of the channel isolation pattern. For example, the first source/drain pattern 150 may be disposed on the first protrusion portion 110PR_1 of the channel isolation pattern 110P. The first source/drain pattern 150 may overlap with the protrusion portion 110PR of the channel isolation pattern in the third direction DR3.

The first source/drain pattern 150 may be connected to the first channel pattern CH1. The first source/drain pattern 150 may be in contact (e.g., direct contact) with the channel isolation pattern 110. In the semiconductor device according to some embodiments, the channel isolation pattern 110 may be disposed between the first source/drain pattern 150 and the first substrate 100. The first area 110_R1 of the channel isolation pattern 110P may be disposed between the first source/drain pattern 150 and the first substrate 100.

The first source/drain pattern 150 may be disposed on at least one side of the gate electrode 120. The first source/drain pattern 150 may be disposed between the gate electrodes 120 adjacent to each other in the first direction DR1. For example, the first source/drain pattern 150 may be disposed on each of both opposing sides of the gate electrode 120. Unlike the illustrated example, the first source/drain pattern 150 may be disposed on one side of the gate electrode 120 and may not be disposed on the other side of the gate electrode 120.

The second source/drain pattern 250 may be disposed on the protrusion portion 110PR of the channel isolation pattern. For example, the second source/drain pattern 250 may be disposed on the second protrusion portion 110PR_2 of the channel isolation pattern 110P. The second source/drain pattern 250 may overlap with the protrusion portion 110PR of the channel isolation pattern in the third direction DR3.

The second source/drain pattern 250 may be in contact (e.g., direct contact) with the channel isolation pattern 110. According to some embodiments, the second source/drain pattern 250 may be connected to the second channel pattern CH2.

The first source/drain pattern 150 and the second source/drain pattern 250 may be included in a source/drain of a transistor including the first channel pattern CH1 and the second channel pattern CH2 as channel areas.

Each of the first source/drain pattern 150 and the second source/drain pattern 250 may include an epitaxial pattern. Each of the first source/drain pattern 150 and the second source/drain pattern 250 include a semiconductor material. Although each of the first source/drain pattern 150 and the second source/drain pattern 250 is illustrated as having a pentagonal or hexagonal cross-section, this is intended only for convenience of illustration, and embodiments of the present disclosure are not limited thereto. Unlike the illustrated example, each of the first source/drain pattern 150 and the second source/drain pattern 250 may have a quadrangle cross section.

Each of the first source/drain pattern 150 and the second source/drain pattern 250 may include, for example, silicon or germanium as an elemental semiconductor material. In addition, each of the first source/drain pattern 150 and the second source/drain pattern 250 may include, for example, a binary compound including two from among carbon (C), silicon (Si), germanium (Ge), and tin (Sn), a ternary compound including three thereof, or a compound obtained by doping a group IV element thereto. In one example, when the first source/drain pattern 150 or the second source/drain pattern 250 is included in the source/drain area of a p-type transistor, the first source/drain pattern 150 or the second source/drain pattern 250 may include a silicon-germanium film. In another example, when the first source/drain pattern 150 or the second source/drain pattern 250 is included in the source/drain area of an n-type transistor, the first source/drain pattern 150 or the second source/drain pattern 250 may include a silicon film. However, embodiments of the present disclosure are not limited thereto.

Each of the first source/drain pattern 150 and the second source/drain pattern 250 may contain impurities doped into a semiconductor material. For example, when the first source/drain pattern 150 or the second source/drain pattern 250 is included in the source/drain area of the p-type transistor, the first source/drain pattern 150 or the second source/drain pattern 250 may contain p-type impurities. For example, the p-type impurity may include at least one from among boron (B) and gallium (Ga). In another example, when the first source/drain pattern 150 or the second source/drain pattern 250 is included in the source/drain area of the n-type transistor, the first source/drain pattern 150 or the second source/drain pattern 250 may contain n-type impurities. For example, the n-type impurity may include at least one from among phosphorus (P), arsenic (As), antimony (Sb), and bismuth (Bi).

Although each of the first source/drain pattern 150 and the second source/drain pattern 250 is illustrated as being embodied as a single film, this is intended only for convenience of illustration and embodiments of the present disclosure are not limited thereto.

A source/drain etch stop film 185 may be disposed on a sidewall of the gate spacer 140 and an upper surface of each of the first source/drain pattern 150 and the second source/drain pattern 250. The source/drain etch stop film 185 may be disposed on the channel isolation pattern 110. For example, the source/drain etch stop film 185 may extend along the upper surface of the plate portion 110PL of the channel isolation pattern 110P.

The source/drain etch stop film 185 may include a material having an etch selectivity with respect to the first interlayer insulating film 190 to be described below. The source/drain etch stop film 185 may include, for example, silicon nitride, silicon oxynitride, silicon oxycarbonitride, silicon boron nitride, silicon oxyboron nitride, silicon oxycarbide, or a combination thereof.

The first interlayer insulating film 190 may be disposed on the source/drain etch stop film 185. The first interlayer insulating film 190 may be disposed on the first source/drain pattern 150 and the second source/drain pattern 250. The first interlayer insulating film 190 may not cover an upper surface of the gate capping pattern 145.

The channel isolation pattern 110 may be disposed between the first substrate 100 and the first interlayer insulating film 190. For example, the channel isolation pattern 110 may be disposed between the source/drain etch stop film 185 and the first substrate 100.

The first interlayer insulating film 190 may include, for example, at least one from among silicon oxide, silicon nitride, silicon oxynitride, and a low dielectric constant material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilyl Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped Silicon Oxide), OSG (SiLK), Amorphous Fluorinated Carbon, silica aerogels, silica xerogels, mesoporous silica, or a combination thereof. However, embodiments of the present disclosure are not limited thereto.

The channel isolation pattern 110 may prevent a leakage current between the first source/drain patterns 150 adjacent to each other in the first direction DR1. In addition, due to the channel isolation pattern 110, vertical levels of the bottom surfaces of the first source/drain patterns 150 arranged in the first direction DR1 may be uniform. Accordingly, performance and reliability of the semiconductor device according to some embodiments may be improved.

A first front source/drain contact 180 may be disposed on the first source/drain pattern 150. The first front source/drain contact 180 may be connected to the first source/drain pattern 150. The first front source/drain contact 180 may extend through the first interlayer insulating film 190 and the source/drain etch stop film 185 so as to be connected to the first source/drain pattern 150.

A second front source/drain contact 280 may be disposed on the second source/drain pattern 250. The second front source/drain contact 280 may be connected to the second source/drain pattern 250. The second front source/drain contact 280 may extend through the first interlayer insulating film 190 and the source/drain etch stop film 185 so as to be connected to the second source/drain pattern 250

Although each of the first front source/drain contact 180 and the second front source/drain contact 280 is illustrated as being embodied as a single film, this is intended only for convenience of illustration and embodiments of the present disclosure are not limited thereto. Each of the first front source/drain contact 180 and the second front source/drain contact 280 may include, for example, a metal, a conductive metal nitride, a conductive metal carbide, a conductive metal oxide, a conductive metal carbonitride, a two-dimensional (2D) material, or a combination thereof. In the semiconductor device according to some embodiments, the two-dimensional material may be a metallic material and/or a semiconductor material. The two-dimensional material (2D material) may include a two-dimensional allotrope or a two-dimensional compound, and may include, for example, at least one from among graphene, molybdenum disulfide (MoS₂), molybdenum diselenide (MoSe₂), tungsten diselenide (WSe₂), and tungsten disulfide (WS₂). However, embodiments of the present disclosure are not limited thereto. That is, since the above-described two-dimensional materials are only listed by way of example, the two-dimensional material that may be included in the semiconductor device of the present disclosure is not limited to the above-described materials.

A first front contact silicide film 155 may be disposed between the first front source/drain contact 180 and the first source/drain pattern 150. A second front contact silicide film 255 may be disposed between the second front source/drain contact 280 and the second source/drain pattern 250. Each of the first front contact silicide film 155 and the second front contact silicide film 255 may include a metal silicide.

A second interlayer insulating film 191 may be disposed on the first interlayer insulating film 190. The second interlayer insulating film 191 may include, for example, at least one from among silicon oxide, silicon nitride, silicon oxynitride, and a low dielectric constant material.

The front wiring structure 195 may be disposed in the second interlayer insulating film 191. The front wiring structure 195 may be connected to the first front source/drain contact 180. According to some embodiments, the front wiring structure 195 may be connected to the second front source/drain contact 280.

The front wiring structure 195 may include a front wiring line 197 and a front wiring via 196. The front wiring line 197 may be connected to the first front source/drain contact 180 by the front wiring via 196. The gate electrode 120 may be disposed between the channel isolation pattern 110 and the front wiring line 197.

Although the front wiring line 197 and the front wiring via 196 are illustrated as being distinguished from each other, this is intended only for convenience of illustration, and embodiments of the present disclosure are not limited thereto. That is, for example, after the front wiring via 196 is formed, the front wiring line 197 may be formed. In another example, the front wiring via 196 and the front wiring line 197 may be simultaneously formed.

Although each of the front wiring line 197 and the front wiring via 196 is illustrated as being embodied as a single film, this is intended only for convenience of illustration, and embodiments of the present disclosure are not limited thereto. Each of the front wiring line 197 and the front wiring via 196 may include, for example, at least one from among a metal, a conductive metal nitride, a conductive metal carbide, a conductive metal oxide, a conductive metal carbonitride, and a two-dimensional (2D) material.

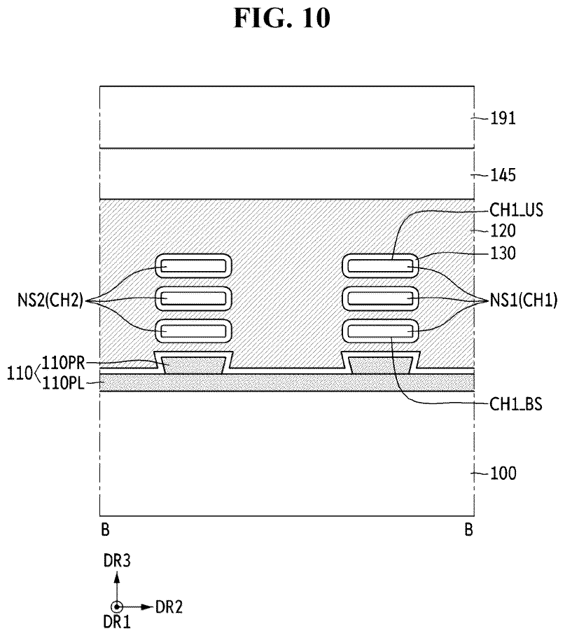

FIGS. 10 to 13 are diagrams for illustrating a semiconductor device according to some embodiments. For convenience of description, differences thereof from embodiments described above with reference to FIGS. 1 to 9 will be mainly described.

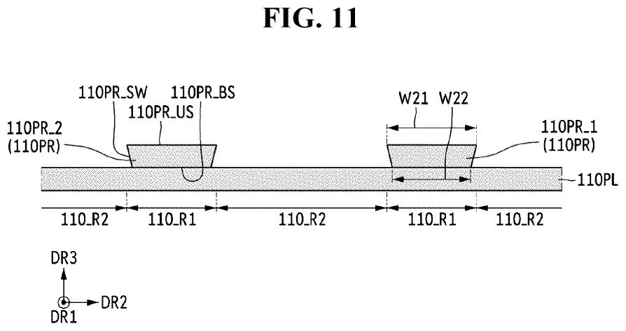

For reference, FIG. 10 is a cross-sectional view taken along a line B-B of FIG. 1. FIGS. 11 to 13 are diagrams for illustrating the channel isolation pattern of FIG. 10, respectively.

Referring to FIGS. 10 to 13, in the semiconductor device according to some embodiments, the width W21 in the second direction DR2 of the upper surface 110PR_US of the protrusion portion of the channel isolation pattern may be greater than the width W22 in the second direction DR2 of the bottom surface 110PR_BS of the protrusion portion of the channel isolation pattern.

The width of the protrusion portion 110PR of the channel isolation pattern 110 may increase as the protrusion portion 110PR extends away from the plate portion 110PL of the channel isolation pattern 110.

In FIG. 11, a sidewall 110PR_SW of the protrusion portion 110PR of the channel isolation pattern 110P may be flat in a cross-sectional view. For example, the sidewall 110PR_SW of the protrusion portion 110SP of the channel isolation pattern 110 may be an inclined surface.

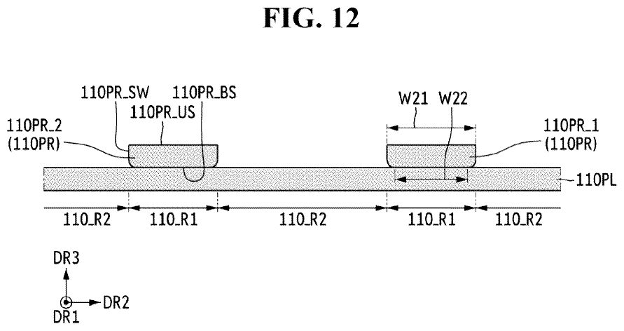

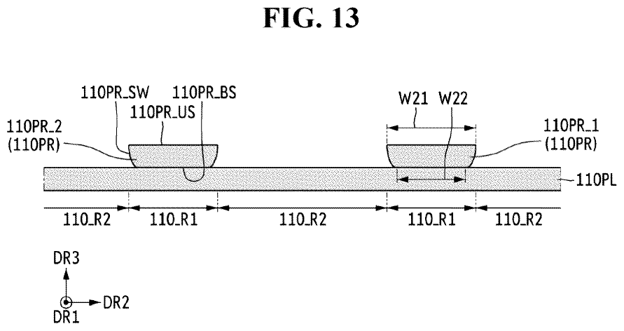

In FIGS. 12 and 13, at least a portion of the sidewall 110PR_SW of the protrusion portion 110PR of the channel isolation pattern 110 may be a curved surface. In FIG. 12, the sidewall 110PR_SW of the protrusion portion 110PR of the channel isolation pattern 110 may be a combination of a flat surface and a curved surface in a cross-sectional view. In FIG. 13, the sidewall 110PR_SW of the protrusion portion 110PR of the channel isolation pattern 110 may be a curved surface in a cross-sectional view.

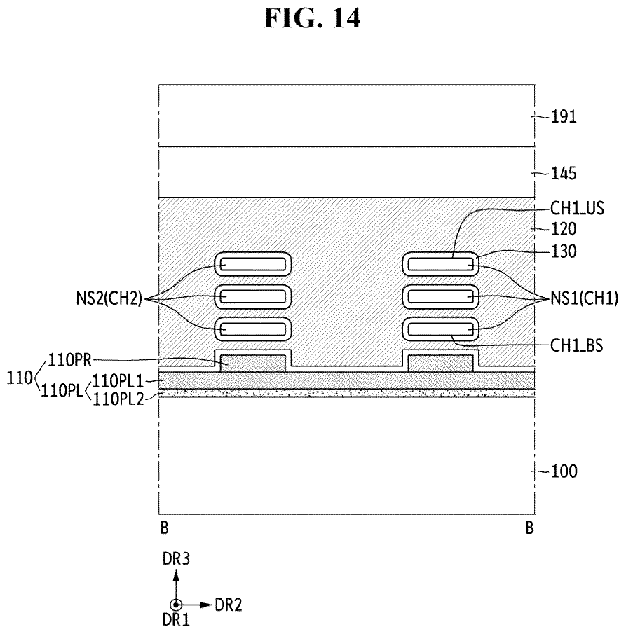

FIGS. 14 to 16 are diagrams for illustrating a semiconductor device according to some embodiments, respectively. For convenience of description, differences thereof from embodiments described above with reference to FIGS. 1 to 9 will be mainly described.

Referring to FIG. 14, in the semiconductor device according to some embodiments, the plate portion 110PL of the channel isolation pattern may include a first channel isolation insulating film 110PL1 and a second channel isolation insulating film 110PL2 sequentially stacked on the first substrate 100.

The first channel isolation insulating film 110PL1 may be disposed between the second channel isolation insulating film 110PL2 and the protrusion portion 110PR of the channel isolation pattern 110. The second channel isolation insulating film 110PL2 may be in contact (e.g., direct contact) with the first substrate 100 and the first channel isolation insulating film 110PL1.

The first channel isolation insulating film 110PL1 may include a material having an etch selectivity with respect to a sacrificial field insulating film (105_SC (see FIG. 32) to be described below. The first channel isolation insulating film 110PL1 may include, but is not limited to, silicon nitride, silicon oxynitride, silicon oxycarbonitride, silicon boron nitride, silicon oxyboron nitride, silicon oxycarbide, or a combination thereof.

The second channel isolation insulating film 110PL2 may include one from among silicon oxide and silicon carbonitride. However, embodiments of the present disclosure are not limited thereto.

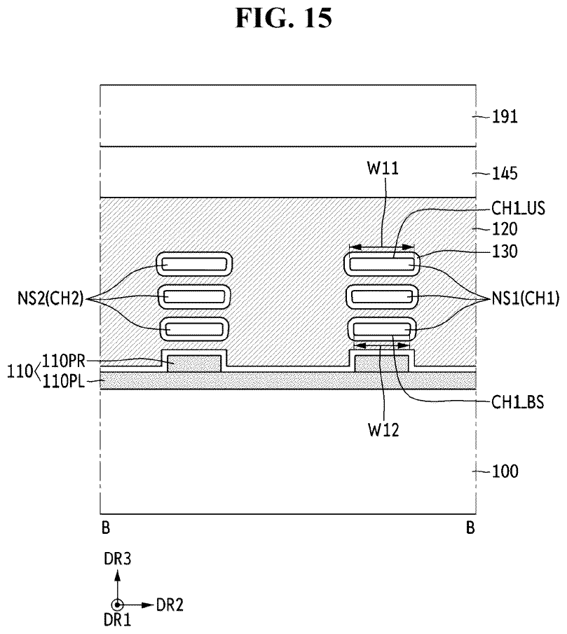

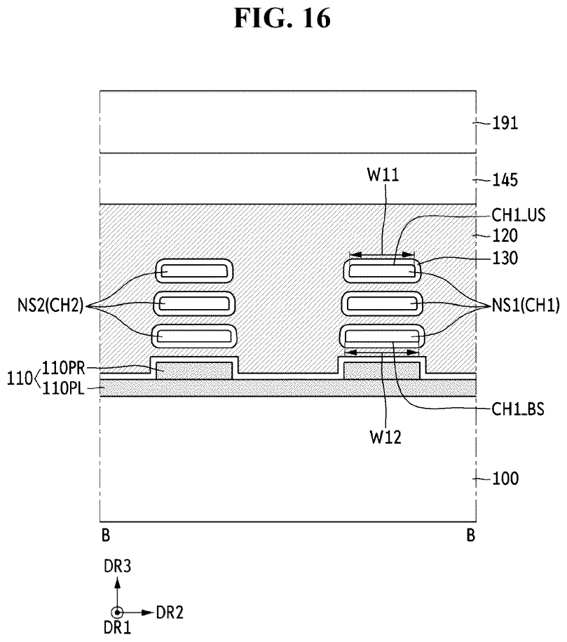

Referring to FIGS. 15 and 16, in the semiconductor device according to some embodiments, the width W11 in the second direction DR2 of the upper surface CH1_US of the first channel pattern may be different from the width W12 in the second direction DR2 of the bottom surface CH1_BS of the first channel pattern.

With reference to FIG. 15, the width W11 in the second direction DR2 of the upper surface CH1_US of the first channel pattern may be greater than the width W12 in the second direction DR2 of the bottom surface CH1_BS of the first channel pattern.

With reference to FIG. 16, the width W11 in the second direction DR2 of the upper surface CH1_US of the first channel pattern may be smaller than the width W12 in the second direction DR2 of the bottom surface CH1_BS of the first channel pattern.

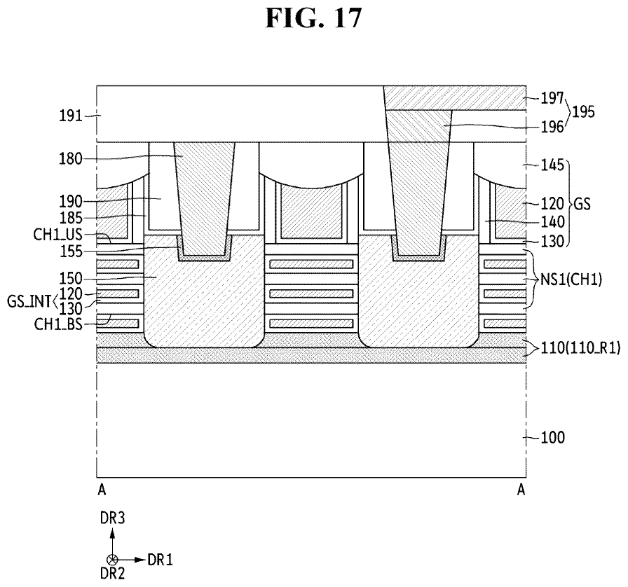

FIGS. 17 to 19 are diagrams for illustrating semiconductor devices according to some embodiments, respectively. For convenience of description, differences thereof from embodiments described above with reference to FIGS. 1 to 9 will be mainly described.

Referring to FIG. 17, in the semiconductor device according to some embodiments, a portion of the first source/drain pattern 150 may protrude into the channel isolation pattern 110.

A portion of the first source/drain pattern 150 may protrude into the first area 110_R1 of the channel isolation pattern 110.

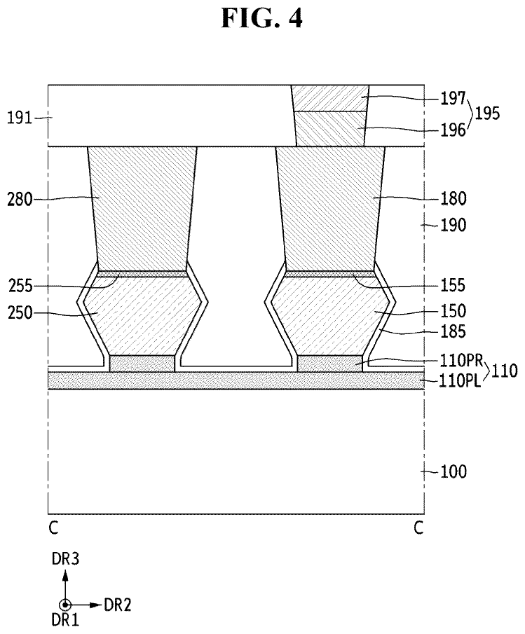

According to some embodiment, a portion of the second source/drain pattern 250 (see FIG. 4) may protrude into the first area 110_R1 of the channel isolation pattern.

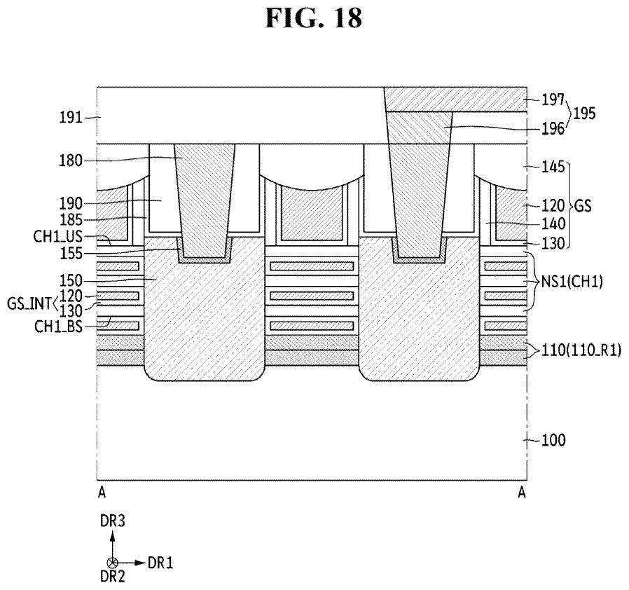

Referring to FIG. 18, in the semiconductor device according to some embodiments, the first source/drain pattern 150 may extend through the channel isolation pattern 110.

The first source/drain pattern 150 may extend through the first area 110_R1 of the channel isolation pattern 110 so as to be in contact (e.g., direct contact) with the first substrate 100.

According to some embodiments, the second source/drain pattern 250 (see FIG. 4) may extend through the channel isolation pattern 110.

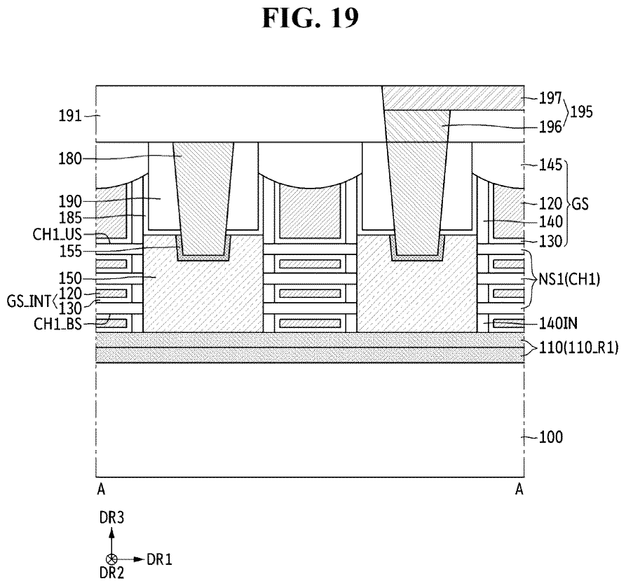

Referring to FIG. 19, the semiconductor device according to some embodiments may include an inner spacer 140IN.

The inner spacer 140IN may be disposed between the first sheet patterns NS1 adjacent to each other in the third direction DR3 and between the channel isolation pattern 110 and the lowest first sheet pattern NS1. The inner spacer 140IN may be in contact (e.g., direct contact) with a portion of the gate insulating film 130 included in the inner gate structure GS_INT.

The inner spacer 140IN may include an insulating material.

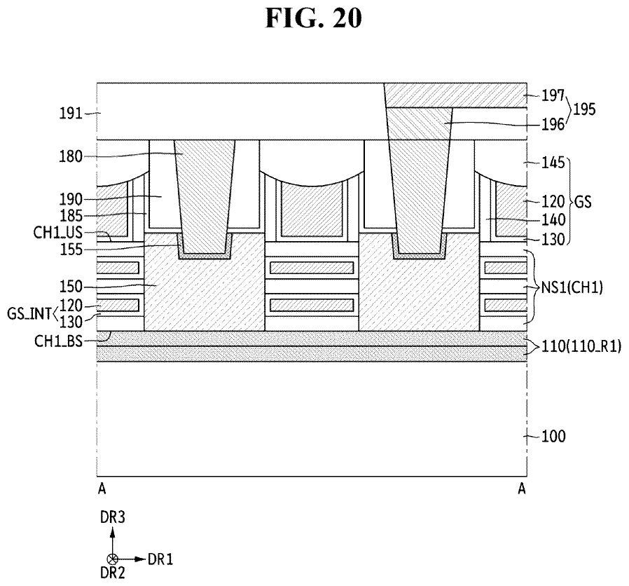

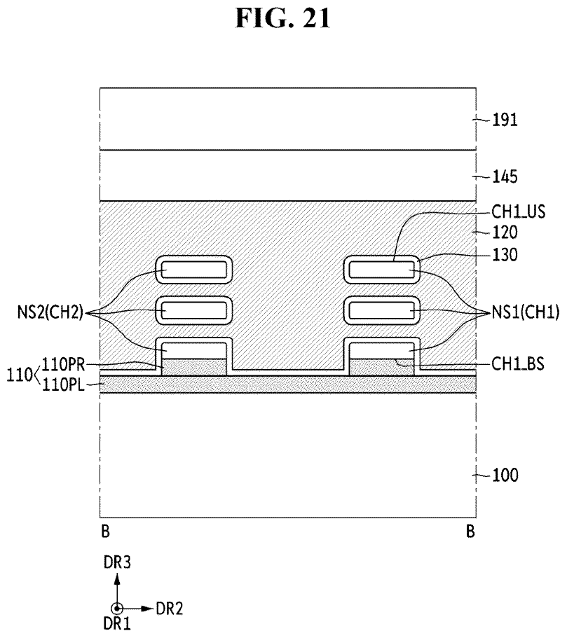

FIGS. 20 and 21 are diagrams for illustrating a semiconductor device according to some embodiments. For convenience of description, differences thereof from embodiments described above with reference to FIGS. 1 to 9 will be mainly described.

Referring to FIGS. 20 and 21, in the semiconductor device according to some embodiments, one of the plurality of first sheet patterns NS1 may be in contact (e.g., direct contact) with the channel isolation pattern 110.

One of the plurality of second sheet patterns NS2 may be in contact (e.g., direct contact) with the channel isolation pattern 110. The lowermost first sheet pattern NS1 among the plurality of first sheet patterns NS1 may be in contact (e.g., direct contact) with the channel isolation pattern 110. The lowermost second sheet pattern NS2 among the plurality of first sheet patterns NS2 may be in contact (e.g., direct contact) with the channel isolation pattern 110.

Each of the first channel pattern CH1 and the second channel pattern CH2 may be in contact (e.g., direct contact) with the protrusion portion 110PR of the channel isolation pattern 110. The bottom surface CH1_BS of the first channel pattern CH1 and the bottom surface of the second channel pattern CH2 may be in contact (e.g., direct contact) with the channel isolation pattern 110.

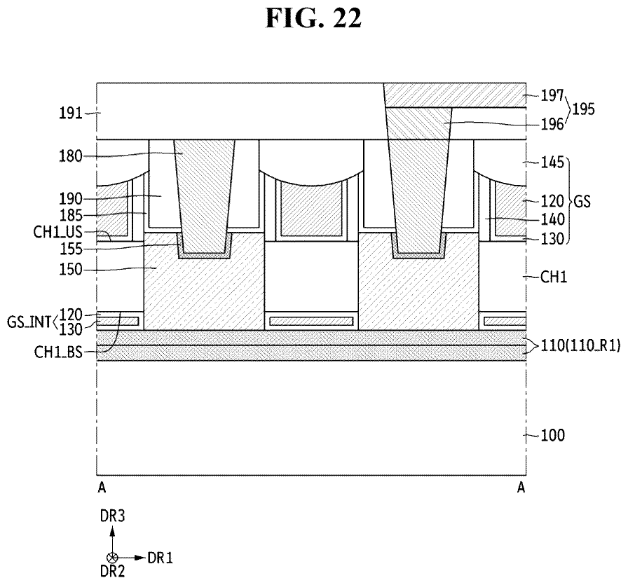

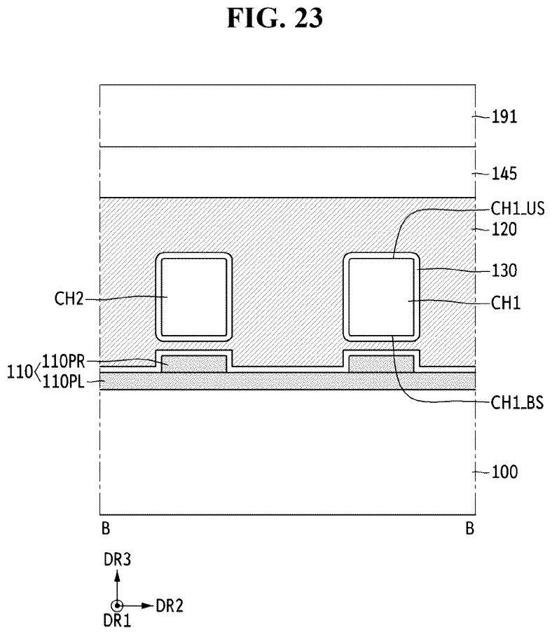

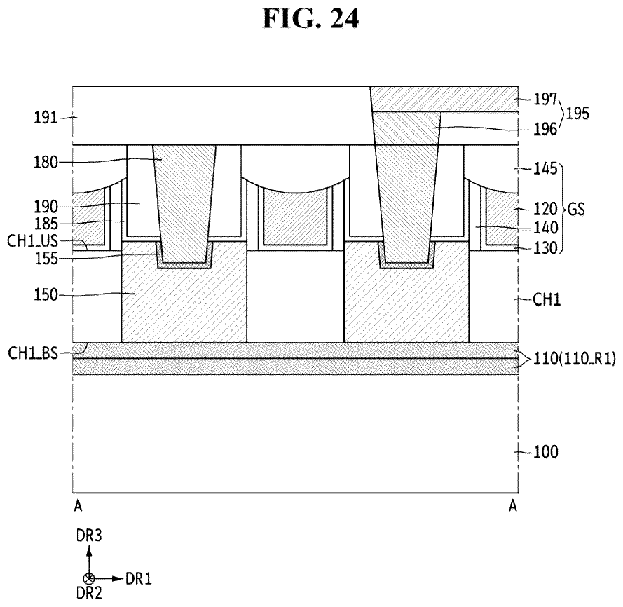

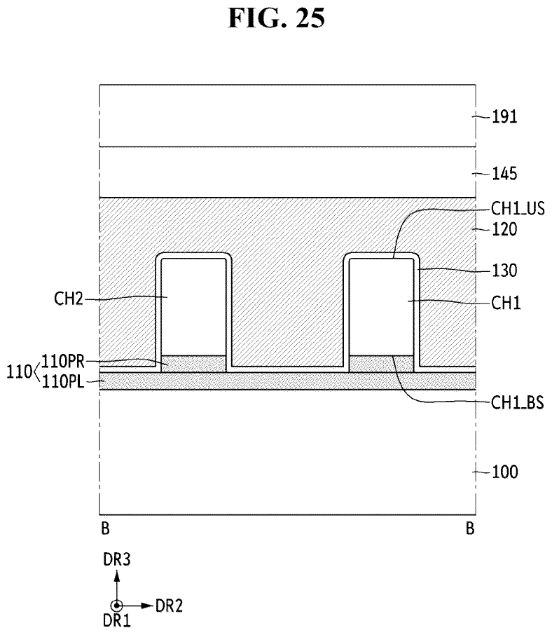

FIGS. 22 and 23 are diagrams for illustrating a semiconductor device according to some embodiments. FIGS. 24 and 25 are diagrams for illustrating a semiconductor device according to some embodiments. For convenience of description, differences thereof from embodiments described above with reference to FIGS. 1 to 9 will be mainly described.

Referring to FIGS. 22 to 25, in the semiconductor device according to some embodiments, each of the first channel pattern CH1 and the second channel pattern CH2 may not include a plurality of sheet patterns spaced apart from each other in the third direction DR3.

With reference to FIGS. 22 and 23, each of the first channel pattern CH1 and the second channel pattern CH2 may not be in direct contact with the channel isolation pattern 110. The gate electrode 120 and the gate insulating film 130 may be disposed between the first channel pattern CH1 and the channel isolation pattern 110 and between the second channel pattern CH2 and the channel isolation pattern 110. The first channel pattern CH1 is described by way of example. The gate electrode 120 and the gate insulating film 130 may surround the upper surface CH1_US of the first channel pattern, the bottom surface CH1_BS of the first channel pattern, and the sidewall of the first channel pattern CH1.

With reference to FIGS. 24 and 25, each of the first channel pattern CH1 and the second channel pattern CH2 may be in contact (e.g., direct contact) with the channel isolation pattern 110. Each of the bottom surface CH1_BS of the first channel pattern CH1 and the bottom surface of the second channel pattern CH2 may be in contact (e.g., direct contact) with the protrusion portion 110PR of the channel isolation pattern 110. For example, the gate electrode 120 and the gate insulating film 130 may be disposed on the upper surface CH1_US of the first channel pattern and the sidewall of the first channel pattern CH1. The gate electrode 120 and the gate insulating film 130 may not be disposed on the bottom surface CH1_BS of the first channel pattern CH1.

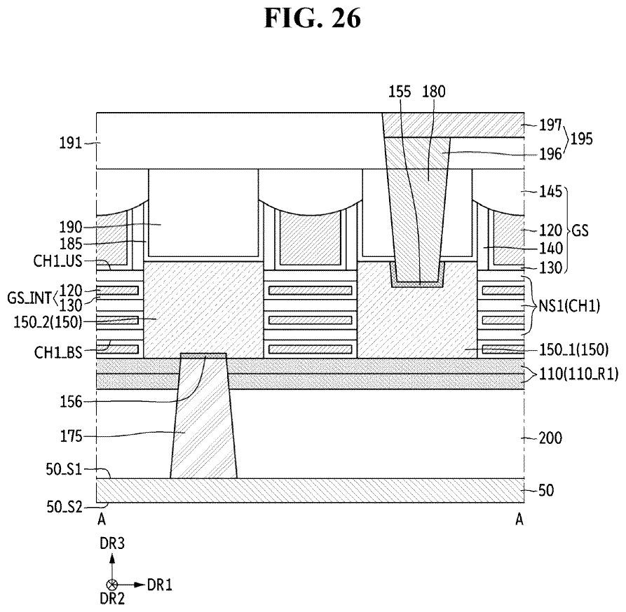

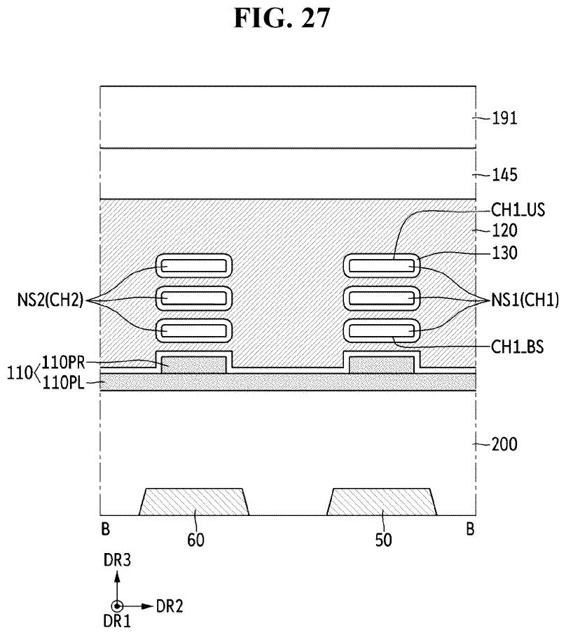

FIGS. 26 and 27 are diagrams for illustrating a semiconductor device according to some embodiments. For convenience of description, differences thereof from embodiments described above with reference to FIGS. 1 to 9 will be mainly described.

Referring to FIGS. 26 and 27, the semiconductor device according to some embodiments may include a first back wiring line 50, a second back wiring line 60, a back source/drain contact 175, the channel isolation pattern 110, the first channel pattern CH1, the second channel pattern CH2, the gate electrode 120, and the first source/drain pattern 150.

Since aspects of the channel isolation pattern 110, the first channel pattern CH1, the second channel pattern CH2, the gate electrode 120, and the first source/drain pattern 150 may be the same as those described with reference to FIGS. 1 to 9, the following description will focus on the differences therebetween.

A second substrate 200 may be provided and include an insulating material. The second substrate 200 may include, but is not limited to, at least one from among silicon oxide, silicon nitride, and silicon oxynitride.

The first back wiring line 50 and the second back wiring line 60 may be disposed in the second substrate 200. Each of the first back wiring line 50 and the second back wiring line 60 may extend in the first direction DR1. The first back wiring line 50 may be spaced apart from the second back wiring line 60 in the second direction DR2.

For example, the first back wiring line 50 and the second back wiring line 60 may be power lines that supply power to the semiconductor device. In another example, the first back wiring line 50 and the second back wiring line 60 may be signal lines for supplying an operation signal of the semiconductor device. In another example, one from among the first back wiring line 50 and the second back wiring line 60 may be a power line, and the other thereof may be a signal line.

The first back wiring line 50 may include a first surface 50_S1 and a second surface 50_S2 opposite to each other in the third direction DR3. The second back wiring line 60 may include a first surface and a second surface opposite to each other in the third direction DR3. The first surface 50_S1 of the first back wiring line 50 and the first surface of the second back wiring line 60 may face towards the first source/drain pattern 150, the channel isolation pattern 110, and the gate electrode 120.

Each of the first back wiring line 50 and the second back wiring line 60 is illustrated as having a trapezoidal cross-section. However, embodiments of the present disclosure are not limited thereto. Unlike the illustrated example, each of the first back wiring line 50 and the second back wiring line 60 may have a rectangular cross-section. A width in the second direction DR2 of the first surface 50_S1 of the first back wiring line may be smaller than a width in the second direction DR2 of the second surface 50_S2 of the first back wiring line.

For example, each of the first back wiring line 50 and the second back wiring line 60 may be formed using a damascene process. After trenches extending in the first direction DR1 are formed in the second substrate 200, each of the trenches may be filled with a conductive material such that each of the first back wiring line 50 and the second back wiring line 60 may be formed.

Although each of the first back wiring line 50 and the second back wiring line 60 is illustrated as having a single conductive film structure, this is intended only for convenience of illustration, and embodiments of the present disclosure are not limited thereto. Each of the first back wiring line 50 and the second back wiring line 60 may include, for example, at least one from among a metal, a conductive metal nitride, a conductive metal carbide, a conductive metal oxide, a conductive metal carbonitride, and a two-dimensional material.

Unlike the illustrated example, each of the first back wiring line 50 and the second back wiring line 60 may extend in the second direction DR2. The first back wiring line 50 may be spaced apart from the second back wiring line 60 in the first direction DR1. In this case, a shape of the cross-sectional view taken along each of lines A-A and B-B of FIG. 1 may be changed.

Unlike the illustrated example, each of the first back wiring line 50 and the second back wiring line 60 may include a line portion and a via portion. For example, the line portion of the first back wiring line 50 may extend in an elongate manner in the first direction DR1. The via portion of the first back wiring line 50 may protrude from the line portion of the first back wiring line 50 in the third direction DR3. The via portion of the first back wiring line 50 may protrude toward the back source/drain contact 175.

The channel isolation pattern 110 may be disposed on the second substrate 200. The channel isolation pattern 110 may be disposed on the first surface 50_S1 of the first back wiring line 50. The channel isolation pattern 110 may be disposed between the first back wiring line 50 and the gate electrode 120 and between the second back wiring line 60 and the gate electrode 120.

The first back wiring line 50 and the second back wiring line 60 may be disposed on the bottom surface CH1_BS of the first channel pattern CH1 and the bottom surface of the second channel pattern CH2, respectively. The front wiring line 197 may be disposed on the upper surface CH1_US of the first channel pattern CH1 and the upper surface of the second channel pattern CH2. The channel isolation pattern 110 and the gate electrode 120 may be disposed between the first back wiring line 50 and the front wiring line 197 and between the second back wiring line 60 and the front wiring line 197.

The channel isolation pattern 110 may be in contact (e.g., direct contact) with the second substrate 200. Unlike the illustrated example, a plate-shaped semiconductor substrate portion may be disposed between the channel isolation pattern 110 and the second substrate 200. The plate-shaped semiconductor substrate portion may be a portion remaining after removing a portion of the first substrate 100 in a process of forming the first back wiring line 50 and the second back wiring line 60.

The first source/drain pattern 150 may include a first front source/drain pattern 150_1 and a first back source/drain pattern 150_2. The first front source/drain pattern 150_1 and the first back source/drain pattern 150_2 may be disposed on the first surface 50_S1 of the first back wiring line 50.

The first front source/drain pattern 150_ 1 and the first back source/drain pattern 150_ 2 may be spaced apart from each other in the first direction DR1 while the first channel pattern CH1 is interposed therebetween.

The first front source/drain contact 180 may be connected to (e.g., electrically connected to) the first front source/drain pattern 150_1. The first front contact silicide film 155 may be disposed between the first front source/drain contact 180 and the first front source/drain pattern 150_1. For example, the first front source/drain pattern 150_1 may not be connected to (e.g., electrically connected to) the first back wiring line 50 and the second back wiring line 60.

The back source/drain contact 175 may be connected to the first back source/drain pattern 150_2. For example, the back source/drain contact 175 may be electrically connected to the first back source/drain pattern 150_2.

The back source/drain contact 175 may be disposed between the first back source/drain pattern 150_2 and the first back wiring line 50. The back source/drain contact 175 may overlap with the first back wiring line 50 and the first back source/drain pattern 150_2 in the third direction DR3.

The back source/drain contact 175 may connect (e.g., electrically connect) the first back source/drain pattern 150_2 and the first back wiring line 50 to each other. The back source/drain contact 175 may be connected to (e.g., electrically connected to) the first back wiring line 50. The back source/drain contact 175 may be connected to (e.g., electrically connected to) the first surface 50_S1 of the first back wiring line.

The back source/drain contact 175 may be disposed in the second substrate 200. The back source/drain contact 175 may extend from the first surface 50_S1 of the first back wiring line to the first back source/drain pattern 150_2. In the semiconductor device according to some embodiments, the back source/drain contact 175 may extend through the channel isolation pattern 110 and be connected to the first back source/drain pattern 150_2.

According to some embodiments, when the plate-shaped semiconductor substrate portion is disposed between the channel isolation pattern 110 and the second substrate 200, a back contact insulating liner may be further disposed between the back source/drain contact 175 and the semiconductor substrate portion. The back contact insulating liner may include an insulating material.

Although the back source/drain contact 175 is illustrated as being embodied as a single film, this is intended only for convenience of illustration, and embodiments of the present disclosure are not limited thereto. The back source/drain contact 175 may include, for example, a metal, a conductive metal nitride, a conductive metal carbide, a conductive metal oxide, a conductive metal carbonitride, a two-dimensional (2D) material, or a combination thereof.

A back contact silicide film 156 may be further disposed between the back source/drain contact 175 and the first back source/drain pattern 150_2. The back contact silicide film 156 may include a metal silicide.

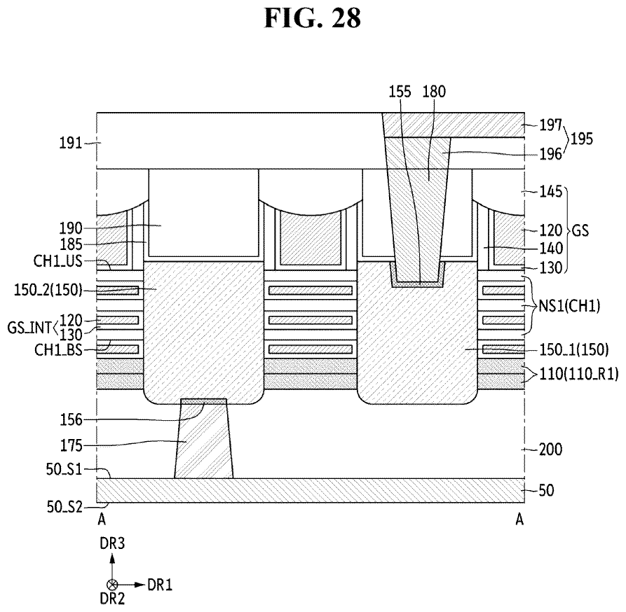

FIG. 28 is a diagram for illustrating a semiconductor device according to some embodiments. For convenience of description, differences thereof from embodiments described above with reference to FIGS. 26 and 27 will be mainly described.

Referring to FIG. 28, in the semiconductor device according to some embodiments, the back source/drain contact 175 may not extend through the channel isolation pattern 110.

The first back source/drain pattern 150_2 may extend through the channel isolation pattern 110. The back source/drain contact 175 may be connected to the first back source/drain pattern 150_2 extending through the channel isolation pattern 110.

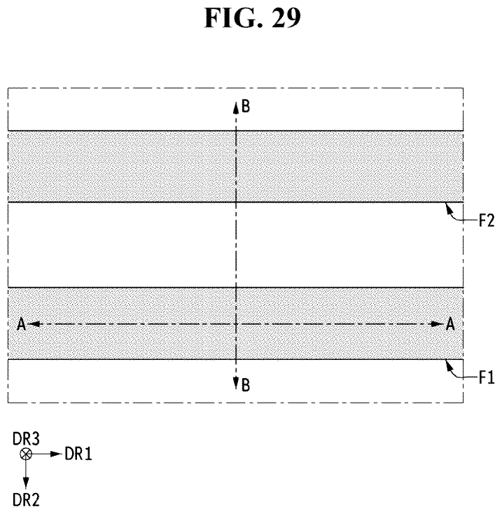

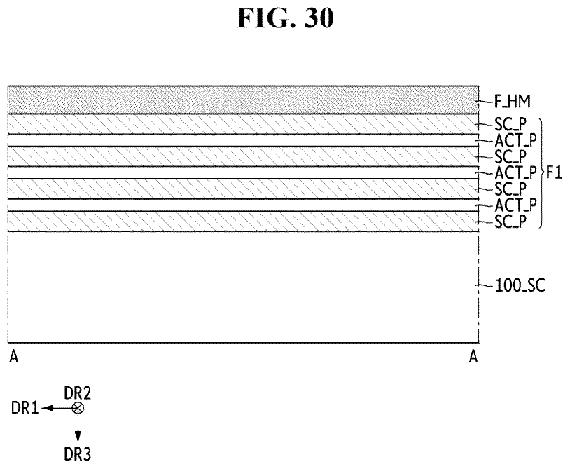

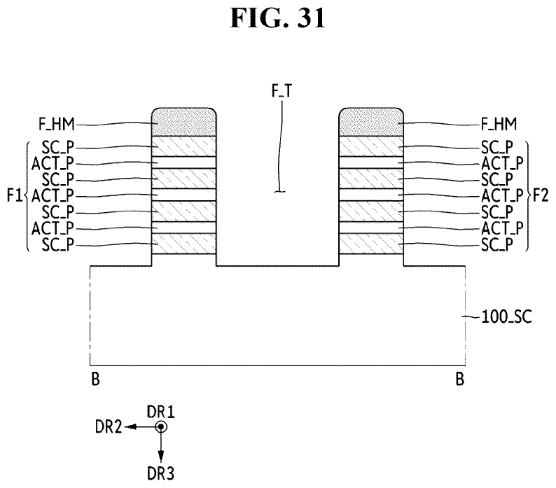

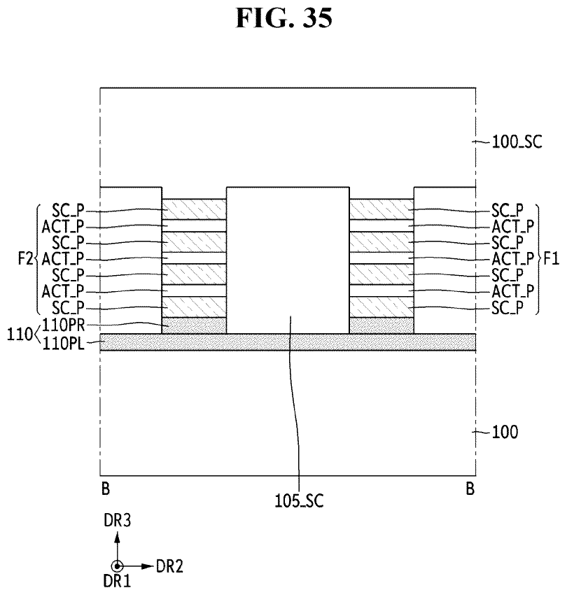

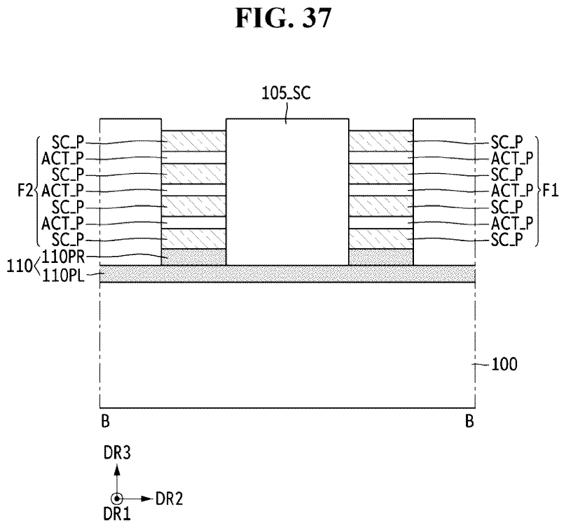

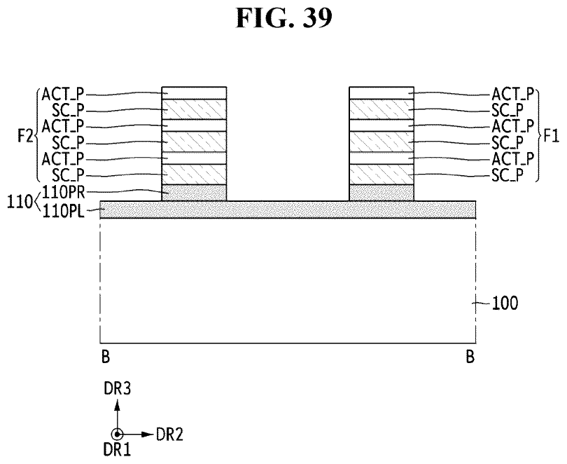

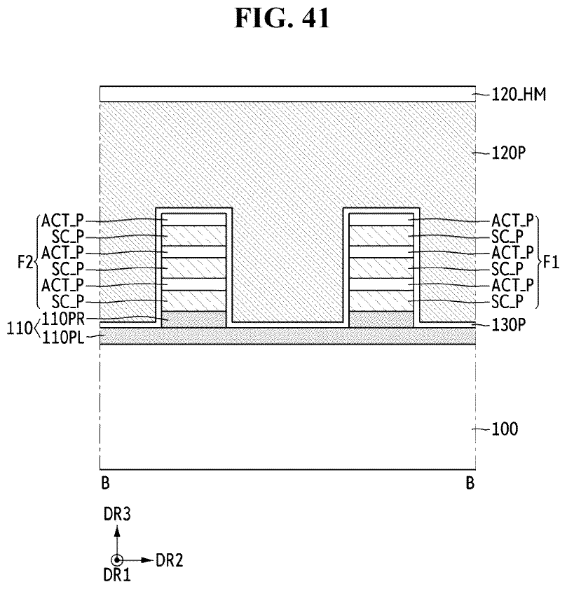

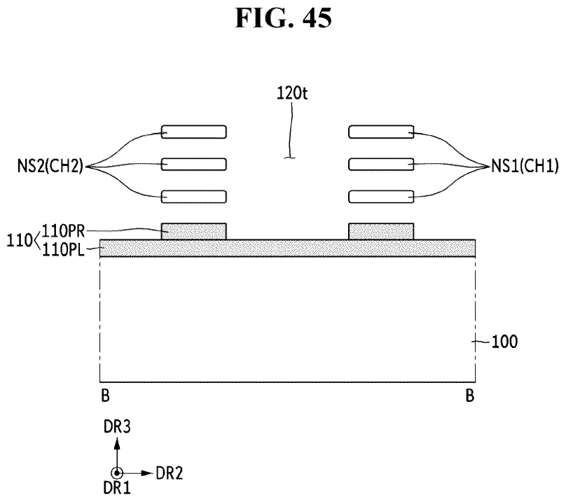

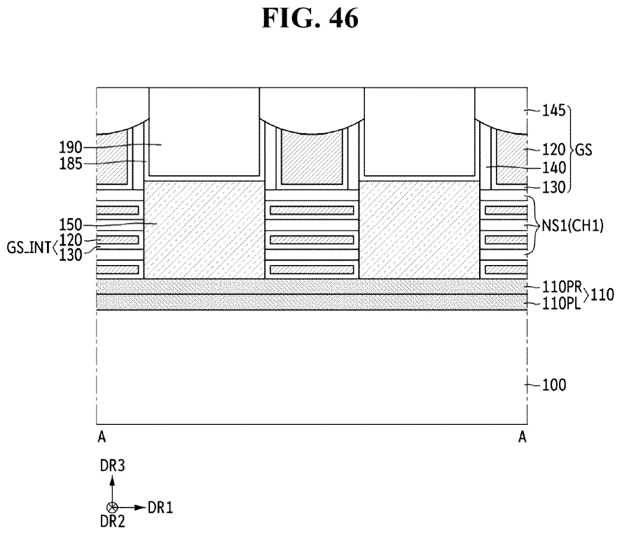

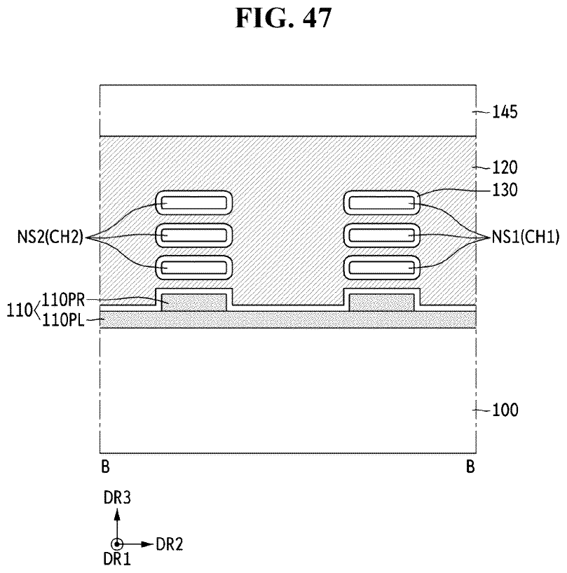

FIGS. 29 to 47 are diagrams illustrating intermediate structures corresponding to intermediate steps of a method for manufacturing a semiconductor device according to some embodiments.

Referring to FIGS. 29 to 31, a first fin-shaped pattern F1 and a second fin-shaped pattern F2 may be formed on a sacrificial substrate 100_SC.

The sacrificial substrate 100_SC may be a silicon substrate, or may include a material other than silicon such as, for example, silicon germanium, silicon germanium on insulator (SGOI), indium antimonide, lead telluride compound, indium arsenide, indium phosphide, gallium arsenide, or gallium antimonide. However, embodiments of the present disclosure are not limited thereto.

Each of the first fin-shaped pattern F1 and the second fin-shaped pattern F2 may extend in the first direction DR1. Each of the first fin-shaped pattern F1 and the second fin-shaped pattern F2 may protrude from the sacrificial substrate 100_SC in the third direction DR3.

The first fin-shaped pattern F1 and the second fin-shaped pattern F2 may be spaced apart from each other in the second direction DR2. The first fin-shaped pattern F1 and the second fin-shaped pattern F2 may be isolated from each other via a fin trench F_T extending in the first direction DR1.

Each of the first fin-shaped pattern F1 and the second fin-shaped pattern F2 may include a plurality of sacrificial patterns SC_P and a plurality of active patterns ACT_P which are alternately stacked on top of each other. For example, the active pattern ACT_P may include a silicon film. The sacrificial pattern SC_P may include a silicon-germanium film.

A fin hard mask pattern F_HM may be disposed on each of the first fin-shaped pattern F1 and the second fin-shaped pattern F2. The fin hard mask pattern F_HM may be used as a mask for forming the first fin-shaped pattern F1 and the second fin-shaped pattern F2. The fin hard mask pattern F_HM may include, but is not limited to, silicon nitride, silicon oxynitride, silicon oxycarbonitride, silicon boron nitride, silicon oxyboron nitride, or silicon oxycarbide.

Referring to FIG. 32, a sacrificial field insulating film 105_SC may be formed on the sacrificial substrate 100_SC.

The sacrificial field insulating film 105_SC may fill the fin trench F_T. The sacrificial field insulating film 105_SC may not cover the fin hard mask pattern F_HM such that the fin hard mask pattern F_HM is exposed. The sacrificial field insulating film 105_SC may include, for example, silicon oxide. However, embodiments of the present disclosure are not limited thereto.

While the sacrificial field insulating film 105_SC is formed, a portion of the fin hard mask pattern F_HM may be removed to reduce a thickness of the fin hard mask pattern F_HM. However, embodiments of the present disclosure are not limited thereto.

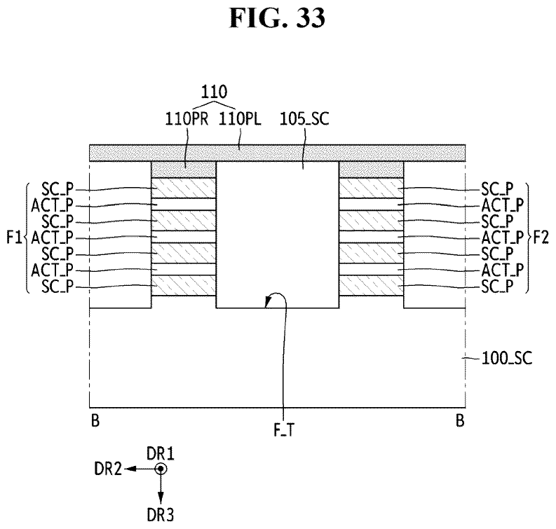

Referring to FIGS. 32 and 33, the channel isolation plate film 110PL may be formed on the fin hard mask pattern F_HM and the sacrificial field insulating film 105_SC.

The channel isolation plate film 110PL may be in contact with the fin hard mask pattern F_HM. Accordingly, the channel isolation pattern 110 including the channel isolation plate film 110PL and the fin hard mask pattern F_HM may be formed. The channel isolation plate film 110PL may be a plate portion of the channel isolation pattern of FIG. 3. The fin hard mask pattern F_HM may be the protrusion portion 110PR of the channel isolation pattern.

Referring to FIGS. 33 to 35, the sacrificial substrate 100_SC on which the channel isolation pattern 110 has been formed may be bonded to the first substrate 100.

The first substrate 100 and the sacrificial substrate 100_SC may be bonded to each other, such that the channel isolation pattern 110 may be disposed between the first substrate 100 and the sacrificial substrate 100_SC.

Unlike the illustrated example, the first substrate 100 and the sacrificial substrate 100_SC may be bonded to each other using a bonding insulating film. In this case, the bonding insulating film may be the second channel isolation insulating film 110PL2 (see FIG. 14).

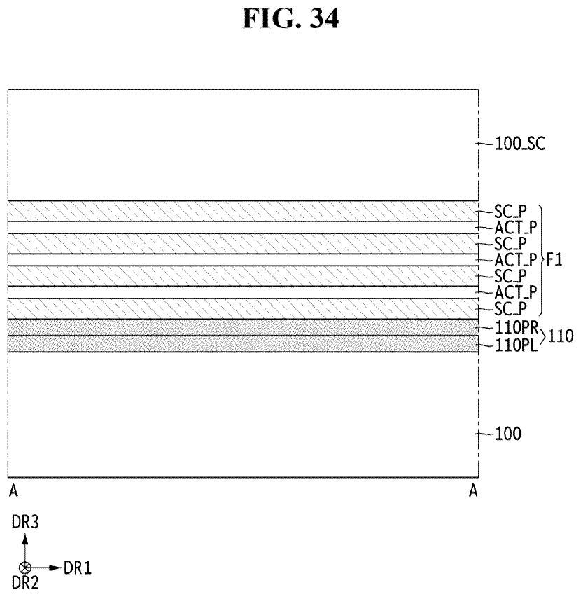

Referring to FIGS. 34 to 37, after the sacrificial substrate 100_SC has been bonded to the first substrate 100, the sacrificial substrate 100_SC may be removed.

The sacrificial substrate 100_SC may be removed to expose the first fin-shaped pattern F1, the second fin-shaped pattern F2, and the sacrificial field insulating film 105_SC. The sacrificial pattern SC_P located farthest from the channel isolation pattern 110 among the sacrificial patterns SC_P included in each of the first fin-type pattern F1 and the second fin-type pattern F2 may be exposed.

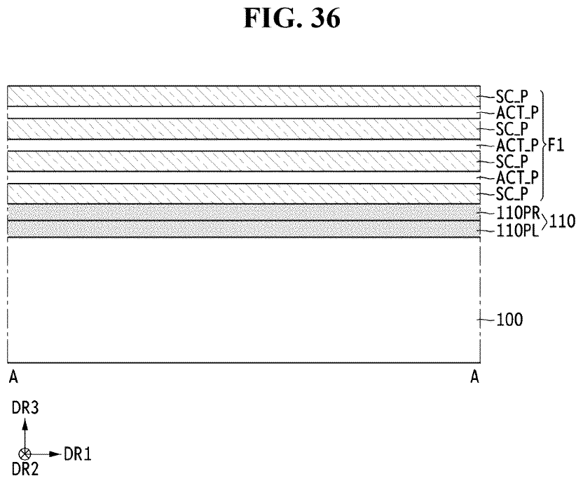

Referring to FIGS. 36 to 39, the sacrificial pattern SC_P located farthest from the channel isolation pattern 110 among the sacrificial patterns SC_P included in each of the first fin-type pattern F1 and the second fin-type pattern F2 may be removed.

After the sacrificial pattern SC_P located farthest from the channel isolation pattern 110 has been removed, the sacrificial field insulating film 105_SC may be removed. As a result, the channel isolation pattern 110 may be exposed.

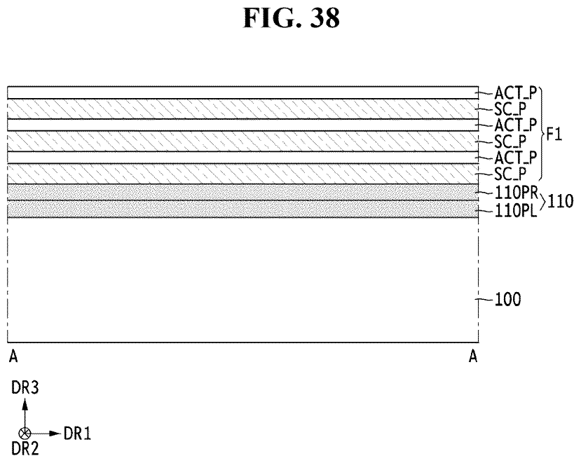

Referring to FIGS. 38 to 41, a dummy gate electrode 120P may be formed on the channel isolation pattern 110.

The dummy gate electrode 120P may be formed on the first fin-shaped pattern F1 and the second fin-shaped pattern F2. The dummy gate electrode 120P may intersect the first fin-shaped pattern F1 and the second fin-shaped pattern F2. The dummy gate electrode 120P may extend in the second direction DR2.

A dummy gate insulating film 130P may be formed between the dummy gate electrode 120P and the first fin-shaped pattern F1, between the dummy gate electrode 120P and the second fin-shaped pattern F2, and between the dummy gate electrode 120P and the channel isolation pattern 110. A dummy gate capping film 120_HM may be formed along an upper surface of the dummy gate electrode 120P.

The dummy gate insulating film 130P may include, for example, silicon oxide. However, embodiments of the present disclosure are not limited thereto. The dummy gate electrode 120P may include, for example, polysilicon. However, embodiments of the present disclosure are not limited thereto. The dummy gate capping film 120_HM may include, for example, silicon nitride. However, embodiments of the present disclosure are not limited thereto.

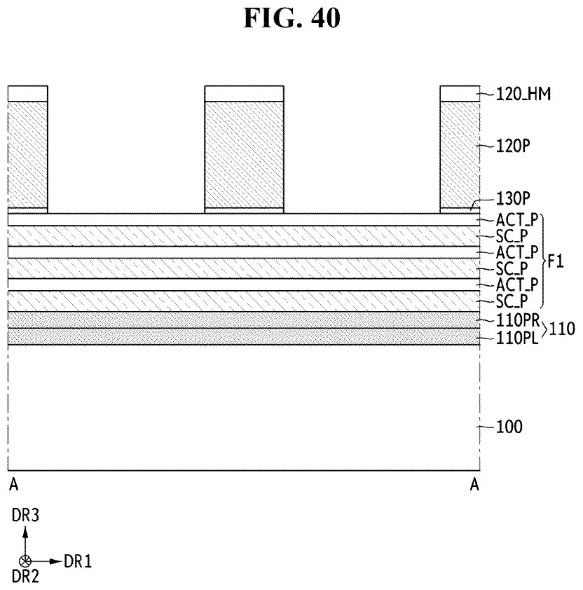

Referring to FIGS. 40 to 42, the gate spacer 140 may be formed on a sidewall of the dummy gate electrode 120P.

While the gate spacer 140 is being formed, a source/drain recess may be formed in the first fin-type pattern F1 using the gate spacer 140 and the dummy gate electrode 120P as the mask.

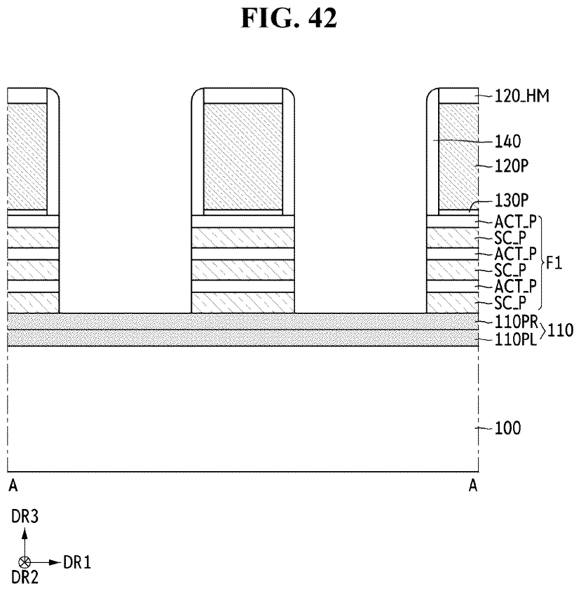

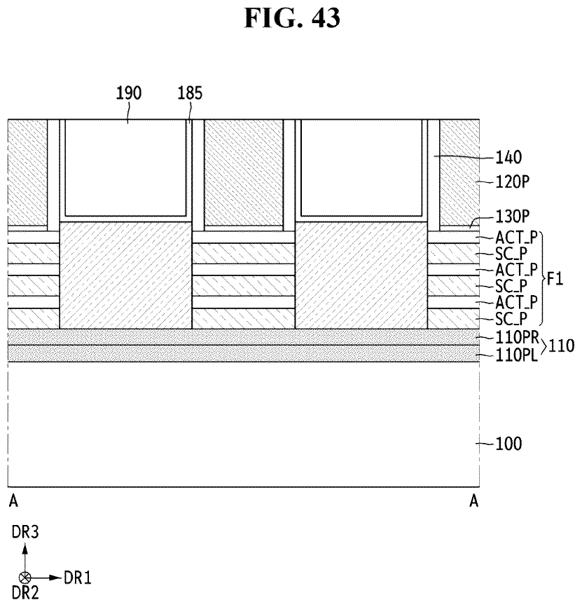

Referring to FIGS. 42 and 43, the first source/drain pattern 150 may be formed on the channel isolation pattern 110.

The first source/drain pattern 150 may fill the source/drain recess.

The source/drain etch stop film 185 and the first interlayer insulating film 190 may be formed on the first source/drain pattern 150.

Subsequently, a portion of the first interlayer insulating film 190, a portion of the source/drain etch stop film 185, and the dummy gate capping film 120_HM may be removed to expose an upper surface of the dummy gate electrode 120P. While the upper surface of the dummy gate electrode 120P is exposed, a portion of the gate spacer 140 may be removed.

Referring to FIGS. 43 to 45, the dummy gate insulating film 130P and the dummy gate electrode 120P may be removed to expose the first fin-shaped pattern F1.

Subsequently, the sacrificial pattern SC_P included in the first fin-type pattern F1 may be removed to form the first channel pattern CH1. The active pattern ACT_P included in the first fin-type pattern F1 may be the first sheet pattern NS1 included in the first channel pattern CH1.

Accordingly, a gate trench 120t may be formed.

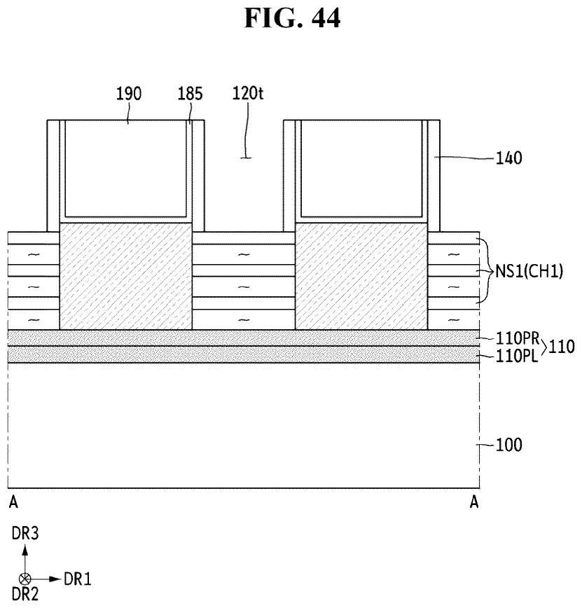

Referring to FIGS. 44 to 47, the gate insulating film 130 and the gate electrode 120 may be formed in the gate trench 120t.

In addition, the gate capping pattern 145 may be formed on the gate electrode 120.

In the manufacturing processes as described above with reference to FIGS. 42 to 47, the dummy gate electrode 120P may be replaced with the gate electrode 120.

According to some embodiments of the present disclosure, a method of manufacturing a semiconductor device may include: providing a channel isolation pattern on a substrate, the channel isolation pattern including a first area and a second area, wherein the second area is in a first direction from the first area; providing a channel pattern on the channel isolation pattern in a second direction crossing the first direction, the channel pattern overlapping with the first area of the channel isolation pattern in the second direction; providing a gate electrode on the first area of the channel isolation pattern and the second area of the channel isolation pattern in the second direction, the gate electrode extending in the first direction; and providing a source/drain pattern, the source/drain pattern connected to the channel pattern, wherein the source/drain pattern is on at least one side of the gate electrode, and wherein a thickness of the channel isolation pattern in the first area of the channel isolation pattern is different from a thickness of the channel isolation pattern in the second area of the channel isolation pattern.

According to some embodiments of the present disclosure, the thickness of the channel isolation pattern in the first area of the channel isolation pattern is greater than the thickness of the channel isolation pattern in the second area of the channel isolation pattern.

According to some embodiments of the present disclosure, the channel pattern is not in direct contact with the channel isolation pattern.

According to some embodiments of the present disclosure, the channel pattern includes a plurality of sheet patterns, the plurality of sheet patterns spaced apart from each other in the second direction.

Although non-limiting example embodiments of the present disclosure have been described with reference to the accompanying drawings, the present disclosure is not limited to the above example embodiments, and embodiments of the present disclosure may be implemented in various different forms. A person skilled in the art may appreciate that embodiments of the present disclosure may be practiced in other concrete forms without departing from the spirit and scope of the present disclosure. Therefore, it should be appreciated that the embodiments as described above are illustrative, not restrictive, in all respects.

What is claimed is:

1. A semiconductor device comprising:
a substrate;
a channel isolation pattern on the substrate, the channel isolation pattern comprising first areas and second areas, wherein the first areas and second areas alternately arranged with each other in a first direction;
a channel pattern on the channel isolation pattern in a second direction crossing the first direction, the channel pattern overlapping with the first area of the channel isolation pattern in the second direction;
a gate electrode on the first area of the channel isolation pattern and the second area of the channel isolation pattern in the second direction, the gate electrode extending in the first direction; and
a source/drain pattern on at least one side of the gate electrode and connected to the channel pattern,
wherein a thickness of the channel isolation pattern in the first area of the channel isolation pattern is different from a thickness of the channel isolation pattern in the second area of the channel isolation pattern.

2. The semiconductor device of claim 1, wherein the thickness of the channel isolation pattern in the first area of the channel isolation pattern is greater than the thickness of the channel isolation pattern in the second area of the channel isolation pattern.

3. The semiconductor device of claim 1, wherein the channel pattern is not in direct contact with the channel isolation pattern.

4. The semiconductor device of claim 3, wherein the channel pattern comprises a plurality of sheet patterns, the plurality of sheet patterns spaced apart from each other in the second direction.

5. The semiconductor device of claim 1, wherein the channel pattern is in direct contact with the channel isolation pattern.

6. The semiconductor device of claim 1, wherein the channel isolation pattern comprises a plate portion and a protrusion portion,
wherein the protrusion portion protrudes from the plate portion in the second direction,
wherein the first area of the channel isolation pattern comprises the protrusion portion and a first portion of the plate portion,
wherein the second area of the channel isolation pattern comprises a second portion of the plate portion, and does not include the protrusion portion.

7. The semiconductor device of claim 6, wherein the plate portion of the channel isolation pattern comprises a first isolation insulating film and a second isolation insulating film on the first isolation insulating film in the second direction.

8. The semiconductor device of claim 1, wherein the source/drain pattern extends through the channel isolation pattern.

9. The semiconductor device of claim 1, wherein the source/drain pattern is in direct contact with the channel isolation pattern,
wherein the first area of the channel isolation pattern is between the source/drain pattern and the substrate.

10. The semiconductor device of claim 1, further comprising:
a source/drain contact connected to the source/drain pattern; and
a wiring line connected to the source/drain contact,
wherein the gate electrode is between the wiring line and the channel isolation pattern.

11. The semiconductor device of claim 1, further comprising:
a source/drain contact connected to the source/drain pattern; and
a wiring line connected to the source/drain contact,
wherein the channel isolation pattern is between the gate electrode and the wiring line, and
wherein the source/drain contact is in the substrate.

12. A semiconductor device comprising:
a substrate;
a channel isolation pattern on the substrate, wherein the channel isolation pattern comprises a plate portion, a first protrusion portion, and a second protrusion portion, wherein each of the first protrusion portion and the second protrusion portion protrudes from the plate portion of the channel isolation pattern in a first direction, wherein the first protrusion portion and the second protrusion portion are spaced apart from each other in a second direction crossing the first direction;
a first channel pattern on the channel isolation pattern in the first direction, and overlapping with the first protrusion portion in the first direction;
a second channel pattern on the channel isolation pattern in the first direction, and overlapping with the second protrusion portion in the first direction;
a gate electrode on the channel isolation pattern, the first channel pattern, and the second channel pattern, and the gate electrode extending in the second direction; and
a source/drain pattern on at least one side of the gate electrode and connected to the first channel pattern.

13. The semiconductor device of claim 12, wherein the first protrusion portion comprises an upper surface and a bottom surface opposite to the upper surface in the first direction,
wherein the bottom surface of the first protrusion portion is in direct contact with the plate portion,
wherein a width in the second direction of the upper surface of the first protrusion portion of is greater than a width in the second direction of the bottom surface of the first protrusion portion.

14. The semiconductor device of claim 13, wherein the first protrusion portion of the channel isolation pattern comprises sidewalls opposite to each other in the second direction,
wherein at least a portion of each of the sidewalls of the first protrusion portion has a curved surface.

15. The semiconductor device of claim 12, wherein the first protrusion portion of the channel isolation pattern comprises an upper surface and a bottom surface opposite to the upper surface in the first direction,
wherein the bottom surface of the first protrusion portion is in contact with the plate portion,
wherein a width in the second direction of the upper surface of the first protrusion portion is equal to a width in the second direction of the bottom surface of the first protrusion portion.

16. The semiconductor device of claim 12, wherein the first channel pattern comprises a plurality of sheet patterns, the plurality of sheet patterns spaced apart from each other in the first direction.

17. The semiconductor device of claim 16, wherein each of the plurality of sheet patterns is spaced apart from the channel isolation pattern in the first direction.

18. The semiconductor device of claim 16, wherein one of the plurality of sheet patterns directly contacts the channel isolation pattern.

19. A semiconductor device comprising:
a substrate;
a channel isolation pattern on the substrate, the channel isolation pattern comprising first areas and second areas, wherein the first areas and the second areas are alternately arranged with each other in a first direction;
a channel pattern on the channel isolation pattern in a second direction crossing the first direction, the channel pattern overlapping with the first area in the second direction, wherein the channel pattern comprises a plurality of sheet patterns that are spaced apart from each other in the second direction;
a gate electrode on the first area of the channel isolation pattern and the second area of the channel isolation pattern, the gate electrode extending in the first direction; and
a source/drain pattern on at least one side of the gate electrode, and connected to the plurality of sheet patterns,
wherein a thickness of the channel isolation pattern in the first area of the channel isolation pattern is greater than a thickness of the channel isolation pattern in the second area of the channel isolation pattern, and
wherein the gate electrode at least partially surrounds the plurality of sheet patterns in a cross-sectional view of the semiconductor device.

20. A semiconductor device of claim 19, further comprising:
a source/drain contact in the substrate and connected to the source/drain pattern; and
a wiring line connected to the source/drain contact.
